(19) United States
(12) Patent Application Publication
(10) Pub. No.: US 2025/0169217 A1
(43) Pub. Date: May 22, 2025

(54) SEMICONDUCTOR DEVICE AND ELECTRONIC DEVICE

(71) Applicant: SONY SEMICONDUCTOR SOLUTIONS CORPORATION, KANAGAWA (JP)

(72) Inventors: TAKANORI OKAMURA, KANAGAWA (JP); YUI YUGA, KANAGAWA (JP); KAZUYUKI TOMIDA, KANAGAWA (JP)

(21) Appl. No.: 18/838,402

(22) PCT Filed: Feb. 13, 2023
(86) PCT No.: PCT/JP2023/004769

§ 371 Date: Aug. 14, 2024

(30) Foreign Application Priority Data
Feb. 22, 2022 (JP) 2022-025473

(51) Int. Cl. H10F 39/00

(52) U.S. Cl. CPC H10F 39/811; H10F 39/018; H10F 39/809

(57) ABSTRACT

Provided is a semiconductor device including: a first substrate (400) including a wiring layer (400T) having an electrode (402) and a semiconductor layer (400S) stacked on the wiring layer; an opening (H4) included in such a manner as to penetrate the semiconductor layer in such a manner as to expose a first region of the electrode; and an insulating film (404) included in the semiconductor layer facing a second region of the electrode not exposed by the opening.

### FIELD

The present disclosure relates to a semiconductor device and an electronic device.

### BACKGROUND

In recent years, since semiconductor devices such as imaging devices are mounted on small-sized electronic devices such as portable terminal devices, it is strongly desired to further miniaturize the semiconductor devices. Therefore, in order to miniaturize the semiconductor devices, a variety of techniques for stacking a plurality of semiconductor substrates or various layers are proposed.

### CITATION LIST

### Patent Literature

Patent Literature 1: JP 2011-114325 A

### SUMMARY

### Technical Problem

In a semiconductor device, for example, an electrode (pad portion) for wire bonding is disposed in an outer peripheral region of a semiconductor substrate. The electrode is electrically connected to an electronic circuit or the like external to the semiconductor device by a wire or the like.

However, depending on a stacked structure of the semiconductor device, a parasitic capacitance may occur in the electrode, and in a case where the parasitic capacitance occurs, a delay, waveform distortion, or others occur in a signal transmitted via the electrode due to the parasitic capacitance. Therefore, it is required to further reduce the parasitic capacitance.

Therefore, the present disclosure proposes a semiconductor device and an electronic device capable of reducing the parasitic capacitance generated in an electrode.

### Solution to Problem

According to the present disclosure, there is provided a semiconductor device including: a first substrate including a wiring layer having an electrode and a semiconductor layer stacked on the wiring layer; an opening included in such a manner as to penetrate the semiconductor layer in such a manner as to expose a first region of the electrode; and an insulating film included in the semiconductor layer facing a second region of the electrode not exposed by the opening.

Furthermore, according to the present disclosure, there is provided an electronic device on which a semiconductor device is mounted. In the electronic device, the semiconductor device includes: a first substrate including a wiring layer having an electrode and a semiconductor layer stacked on the wiring layer; an opening included in such a manner as to penetrate the semiconductor layer in such a manner as to expose a first region of the electrode; and an insulating film included in the semiconductor layer facing a second region of the electrode not exposed by the opening.

### BRIEF DESCRIPTION OF DRAWINGS

FIG. 1 is a block diagram illustrating an example of a functional configuration of an imaging device 1.

FIG. 2 is a schematic plan view illustrating a schematic configuration of an imaging device 1 of a comparative example.

FIG. 3 is a schematic diagram illustrating a cross-sectional structure taken along line III-III′ illustrated in FIG. 2.

FIG. 4 is a schematic diagram illustrating the main part of a cross-sectional structure of an imaging device 1 of a comparative example (part 1).

FIG. 5 is a schematic diagram illustrating the main part of a cross-sectional structure of an imaging device 1 of a comparative example (part 2).

FIG. 6 is a schematic diagram illustrating the main part of a cross-sectional structure of an embodiment of the disclosure (part 1).

FIG. 7 is a schematic diagram illustrating the main part of a cross-sectional structure of the embodiment of the disclosure (part 2).

FIG. 8 is a schematic diagram illustrating the main part of a cross-sectional structure of the embodiment of the disclosure (part 3).

FIG. 9 is a schematic diagram illustrating the main part of a planar structure of a first embodiment of the disclosure.

FIG. 10 is a schematic diagram illustrating the main part of a planar structure of a second embodiment of the disclosure.

FIG. 11 is a schematic diagram illustrating the main part of a planar structure of a third embodiment of the disclosure.

FIG. 12 is a schematic diagram illustrating the main part of a planar structure of a fourth embodiment of the disclosure.

FIG. 13 is a schematic diagram illustrating the main part of a planar structure of a fifth embodiment of the disclosure.

FIG. 14A is a schematic diagram illustrating the main part of a planar structure of a sixth embodiment of the disclosure.

FIG. 14B is a schematic diagram illustrating the main part of a cross-sectional structure of the sixth embodiment of the disclosure.

FIG. 15A is a schematic diagram illustrating the main part of a planar structure of a seventh embodiment of the disclosure.

FIG. 15B is a schematic diagram illustrating the main part of a cross-sectional structure of the seventh embodiment of the disclosure.

FIG. 16 is a schematic diagram illustrating the main part of a cross-sectional structure of an eighth embodiment of the disclosure.

FIG. 17A is an explanatory diagram illustrating a part of a manufacturing method of the imaging device 1 according to the first embodiment of the disclosure (part 1).

FIG. 17B is an explanatory diagram illustrating a part of the manufacturing method of the imaging device 1 according to the first embodiment of the disclosure (part 2).

FIG. 17C is an explanatory diagram illustrating a part of the manufacturing method of the imaging device 1 according to the first embodiment of the disclosure (part 3).

FIG. 17D is an explanatory diagram illustrating a part of the manufacturing method of the imaging device 1 according to the first embodiment of the disclosure (part 4).

FIG. 17E is an explanatory diagram illustrating a part of the manufacturing method of the imaging device 1 according to the first embodiment of the disclosure (part 5).

FIG. 17F is an explanatory diagram illustrating a part of the manufacturing method of the imaging device 1 according to the first embodiment of the disclosure (part 6).

FIG. 17G is an explanatory diagram illustrating a part of the manufacturing method of the imaging device 1 according to the first embodiment of the disclosure (part 7).

FIG. 17H is an explanatory diagram illustrating a part of the manufacturing method of the imaging device 1 according to the first embodiment of the disclosure (part 8).

FIG. 17I is an explanatory diagram illustrating a part of the manufacturing method of the imaging device 1 according to the first embodiment of the disclosure (part 9).

FIG. 17J is an explanatory diagram illustrating a part of the manufacturing method of the imaging device 1 according to the first embodiment of the disclosure (part 10).

FIG. 17K is an explanatory diagram illustrating a part of the manufacturing method of the imaging device 1 according to the first embodiment of the disclosure (part 11).

FIG. 18A is a schematic diagram illustrating the main part of a cross-sectional structure of a tenth embodiment of the disclosure.

FIG. 18B is a schematic diagram illustrating the main part of a planar structure of the tenth embodiment of the disclosure.

FIG. 19A is a schematic diagram illustrating the main part of a planar structure of a modification 1-1 of the tenth embodiment of the disclosure.

FIG. 19B is a schematic diagram illustrating the main part of a planar structure of a modification 1-2 of the tenth embodiment of the disclosure.

FIG. 20A is a schematic diagram illustrating the main part of a cross-sectional structure of a modification 2-1 of the tenth embodiment of the disclosure.

FIG. 20B is a schematic diagram illustrating the main part of a cross-sectional structure of a modification 2-2 of the tenth embodiment of the disclosure.

FIG. 21A is a schematic diagram illustrating the main part of a cross-sectional structure of a modification 3-1 of the tenth embodiment of the disclosure.

FIG. 21B is a schematic diagram illustrating the main part of a planar structure of a modification 3-1 of the tenth embodiment of the disclosure.

FIG. 22A is a schematic diagram illustrating the main part of a planar structure of a modification 3-2 of the tenth embodiment of the disclosure.

FIG. 22B is a schematic diagram illustrating the main part of a planar structure of a modification 3-3 of the tenth embodiment of the disclosure.

FIG. 22C is a schematic diagram illustrating the main part of a planar structure of a modification 3-4 of the tenth embodiment of the disclosure.

FIG. 23A is a schematic diagram illustrating the main part of a cross-sectional structure of a fourth modification of the tenth embodiment of the disclosure.

FIG. 23B is a schematic diagram illustrating the main part of a planar structure of the fourth modification of the tenth embodiment of the disclosure.

FIG. 24A is a schematic diagram illustrating the main part of a cross-sectional structure of a fifth modification of the tenth embodiment of the disclosure.

FIG. 24B is a schematic diagram illustrating the main part of a planar structure of the fifth modification of the tenth embodiment of the disclosure.

FIG. 25 is a schematic diagram illustrating the main part of a cross-sectional structure of a sixth modification of the tenth embodiment of the disclosure.

FIG. 26 is a schematic diagram illustrating the main part of a cross-sectional structure of a seventh modification of the tenth embodiment of the disclosure.

FIG. 27 is a schematic diagram illustrating the main part of a cross-sectional structure of an eighth modification of the tenth embodiment of the disclosure.

FIG. 28A is an explanatory diagram illustrating a part of a manufacturing method of an imaging device 10 according to the tenth embodiment of the disclosure (part 1).

FIG. 28B is an explanatory diagram illustrating a part of the manufacturing method of the imaging device 10 according to the tenth embodiment of the disclosure (part 2).

FIG. 28C is an explanatory diagram illustrating a part of the manufacturing method of the imaging device 10 according to the tenth embodiment of the disclosure (part 3).

FIG. 28D is an explanatory diagram illustrating a part of the manufacturing method of the imaging device 10 according to the tenth embodiment of the disclosure (part 4).

FIG. 28E is an explanatory diagram illustrating a part of the manufacturing method of the imaging device 10 according to the tenth embodiment of the disclosure (part 5).

FIG. 28F is an explanatory diagram illustrating a part of the manufacturing method of the imaging device 10 according to the tenth embodiment of the disclosure (part 6).

FIG. 28G is an explanatory diagram illustrating a part of the manufacturing method of the imaging device 10 according to the tenth embodiment of the disclosure (part 7).

FIG. 29A is an explanatory diagram illustrating a part of another manufacturing method of the imaging device 10 according to the tenth embodiment of the disclosure (part 1).

FIG. 29B is an explanatory diagram illustrating a part of the other manufacturing method of the imaging device 10 according to the tenth embodiment of the disclosure (part 2).

FIG. 29C is an explanatory diagram illustrating a part of the other manufacturing method of the imaging device 10 according to the tenth embodiment of the disclosure (part 3).

FIG. 29D is an explanatory diagram illustrating a part of the other manufacturing method of the imaging device 10 according to the tenth embodiment of the disclosure (part 4).

FIG. 29E is an explanatory diagram illustrating a part of the other manufacturing method of the imaging device 10 according to the tenth embodiment of the disclosure (part 5).

FIG. 29F is an explanatory diagram illustrating a part of the other manufacturing method of the imaging device 10 according to the tenth embodiment of the disclosure (part 6).

FIG. 29G is an explanatory diagram illustrating a part of the other manufacturing method of the imaging device 10 according to the tenth embodiment of the disclosure (part 7).

FIG. 30 is an explanatory diagram illustrating an example of a schematic functional configuration of a camera.

FIG. 31 is a block diagram illustrating an example of a schematic functional configuration of a smartphone.

### DESCRIPTION OF EMBODIMENTS

Hereinafter, preferred embodiments of the present disclosure will be described in detail by referring to the accompanying drawings. Note that, in the present specification and the drawings, components having substantially the same functional configuration are denoted by the same symbols, and redundant description is omitted.

In addition, the drawings referred to in the following description are drawings for describing and promoting understanding of an embodiment of the present disclosure, and shapes, dimensions, ratios, and the like illustrated in the drawings may be different from actual ones for the sake of facilitating understanding. Furthermore, an imaging device illustrated in the drawings can be modified in design as appropriate in consideration of the following description and known technology.

The description of specific lengths or shapes in the following description does not mean only the same values as mathematically defined numerical values or geometrically defined shapes. Specifically, the description of a specific length or shape in the following description includes a case where there is an allowable difference (error or distortion) in imaging devices (semiconductor devices), manufacturing processes thereof, or use or operation thereof, and a shape similar to the shape. For example, in the following description, the expression of “circular shape” or “substantially circular shape” means that the shape is not limited to a perfect circle but also includes shapes similar to a perfect circle such as an elliptical shape.

In the following description of circuits (electrical connection), unless otherwise specified, “electrically connected” means that a plurality of elements is connected such that electricity (signal) is conducted. In addition, “electrically connected” in the following description includes not only a case where a plurality of elements is directly and electrically connected but also a case where a plurality of elements is indirectly and electrically connected via other elements.

Hereinafter, modes for carrying out the present disclosure will be described in detail with reference to the drawings. Note that the description will be given in the following order.
1. Background of Creation of Embodiments of Present Disclosure by Present Inventors
   1.1 Functional Configuration of Imaging Device 1
   1.2 Schematic Configuration of Imaging Device 1 of Comparative Example
   1.3 Background and Overview of Embodiments of Present Disclosure
2. First Embodiment
3. Second Embodiment
4. Third Embodiment
5. Fourth Embodiment
6. Fifth Embodiment
7. Sixth Embodiment
8. Seventh Embodiment
9. Eighth Embodiment
10. Ninth Embodiment
11. Tenth Embodiment
   11.1 Embodiments
   11.2 First Modification
   11.3 Second Modification
   11.4 Third Modification
   11.5 Fourth Modification
   11.6 Fifth Modification
   11.7 Sixth Modification
   11.8 Seventh Modification
   11.9 Eighth Modification
   11.10 Manufacturing Method
12. Summary
13. Application Examples
   13.1 Application Example to Camera
   13.2 Application Example to Smartphone
14. Supplements

### 1. Background of Creation of Embodiments of Present Disclosure by Present Inventors

### 1.1 Functional Configuration of Imaging Device 1

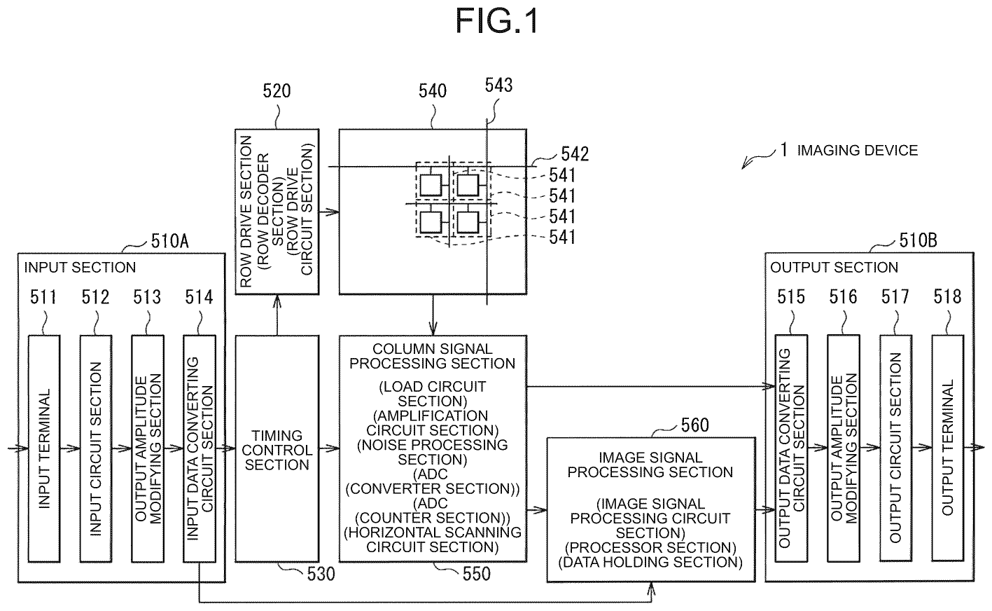

First, before describing the details of embodiments of the present disclosure, the background that led the present inventors to create embodiments of the present disclosure will be described. First, an example of a functional configuration of an imaging device 1 to which an embodiment of the present disclosure can be applied will be described with reference to FIG. 1. FIG. 1 is a block diagram illustrating an example of a functional configuration of the imaging device 1.

As illustrated in FIG. 1, the imaging device 1 can mainly include, for example, an input section 510A, a row drive section 520, a timing control section 530, a pixel array section 540, a column signal processing section 550, an image signal processing section 560, and an output section 510B. Hereinafter, each functional section of the imaging device 1 will be described.

### Pixel Array Section 540

In the pixel array section 540, pixels 541 are repeatedly arranged in an array. Note that, in the present specification, for convenience, the row direction may be referred to as an H direction, and the column direction orthogonal to the row direction may be referred to as a V direction. Each of the pixels 541 includes a photodiode (photoelectric conversion element) PD. Furthermore, in the imaging device 1, for example, one pixel circuit is provided for each pixel 541 or multiple pixels 541. For example, by operating this pixel circuit in a time division manner, pixel signals of the respective pixels 541 can be sequentially read out. In the pixel array section 540, a plurality of row drive signal lines 542 and a plurality of vertical signal lines (column readout lines) 543 are included together with the pixels 541. A row drive signal line 542 drives pixels 541 arrayed side by side in the row direction in the pixel array section 540. Furthermore, pixel signals can be read from respective pixels 541 by a vertical signal line (column readout line) 543.

### Row Drive Section 520

The row drive section 520 can include, for example, a row address control section that determines a position of a row for driving pixels, in other words, a row decoder section, and a row drive circuit section that generates signals for driving the pixels 541.

### Column Signal Processing Section 550

The column signal processing section 550 includes a load circuit section that is, for example, electrically connected to the vertical signal lines 543 and forms a source follower circuit with the pixels 541. The column signal processing section 550 may further include an amplification circuit section that amplifies signals read from the pixels 541 via the vertical signal lines 543. The column signal processing section 550 may also include a noise processing section. In the noise processing section, for example, the noise level of the system can be removed from the signals read from the pixels 541 as a result of photoelectric conversion.

The column signal processing section 550 also includes, for example, an analog-to-digital converter (ADC). The analog-to-digital converter can convert signals read from the pixels 541 or analog signals having been subjected to the noise processing into digital signals. The ADC includes, for example, a comparator section and a counter section. In the comparator section, an analog signal to be converted is compared with a reference signal to be compared to. In the counter section, the time until the comparison result in the comparator section is inverted is measured. The column signal processing section 550 may include a horizontal scanning circuit section that performs control of scanning a reading column.

### Timing Control Section 530

The timing control section 530 can supply a signal for controlling timing to the row drive section 520 and the column signal processing section 550 on the basis of a reference clock signal or a timing control signal input to the device.

### Image Signal Processing Section 560

The image signal processing section 560 is a circuit that performs various types of signal processing on data obtained as a result of photoelectric conversion, in other words, data obtained as a result of an imaging operation in the imaging device 1. The image signal processing section 560 includes, for example, an image signal processing circuit section and a data holding section. The image signal processing section 560 may further include a processor section. One example of signal processing executed in the image signal processing section 560 is tone curve correction processing of providing a large number of tones in a case where analog-digital (AD) converted imaging data is data capturing an image of a dark subject and reducing the number of tones in a case where the AD converted imaging data is data capturing an image of a bright subject. In this case, it is desirable to store the characteristic data of the tone curve in the data holding section of the image signal processing section 560 in advance regarding based on what type of tone curve the tones of the imaging data are to be corrected.

### Input Section 510A

The input section 510A is, for example, a functional section for inputting the reference clock signal, the timing control signal, the characteristic data, and others from the outside of the device to the imaging device 1. The timing control signal is, for example, a vertical synchronization signal, a horizontal synchronization signal, or the like. The characteristic data is, for example, data to be stored in the data holding section of the image signal processing section 560. The input section 510A can include, for example, an input terminal 511, an input circuit section 512, an input amplitude modifying section 513, an input data converting circuit section 514, and a power supply section (not illustrated).

Specifically, the input terminal 511 is an external terminal for inputting data. The input circuit section 512 is for ingesting a signal input to the input terminal 511 into the imaging device 1. The input amplitude modifying section 513 can modify the amplitude of the signal ingested by the input circuit section 512 to an amplitude that is easily used inside the imaging device 1. The input data converting circuit section 514 can modify the arrangement of data rows of input data. The input data converting circuit section 514 includes, for example, a serial-parallel conversion circuit. In this serial-parallel conversion circuit, serial signals received as input data can be converted into parallel signals. Note that, in the input section 510A, the input amplitude modifying section 513 and the input data converting circuit section 514 may be omitted. The power supply section can supply power set to various voltages required inside the imaging device 1 using the power supplied from the outside to the imaging device 1. In a case where the imaging device 1 is electrically connected to an external memory device, the input section 510A may include a memory interface circuit that receives data from the external memory device. Examples of the external memory device include a flash memory, a static random access memory (SRAM), a dynamic random access memory (DRAM), or the like.

### Output Section 510B

The output section 510B outputs image data to the outside of the device. The image data is, for example, image data captured by the imaging device 1, image data having been subjected to signal processing by the image signal processing section 560, and the like. The output section 510B can include, for example, an output data converting circuit section 515, an output amplitude modifying section 516, an output circuit section 517, and an output terminal 518.

Specifically, the output data converting circuit section 515 includes, for example, a parallel-serial conversion circuit, and the output data converting circuit section 515 can convert parallel signals used inside the imaging device 1 into serial signals. The output amplitude modifying section 516 can modify the amplitude of a signal used inside the imaging device 1. By modifying the amplitude, the signal whose amplitude has been modified can be easily used by an external device connected externally to the imaging device 1. The output circuit section 517 outputs data from the inside of the imaging device 1 to the outside of the device, and the output circuit section 517 can drive wiring outside the imaging device 1 electrically connected to the output terminal 518. Furthermore, the output terminal 518 can output data from the imaging device 1 to the outside of the device. In the output section 510B, the output data converting circuit section 515 and the output amplitude modifying section 516 may be omitted. Moreover, in a case where the imaging device 1 is electrically connected to an external memory device, the output section 510B may include a memory interface circuit that outputs data to the external memory device. Examples of the external memory device include a flash memory, an SRAM, a DRAM, and the like.

### 1.2 Schematic Configuration of Imaging Device 1 of Comparative Example

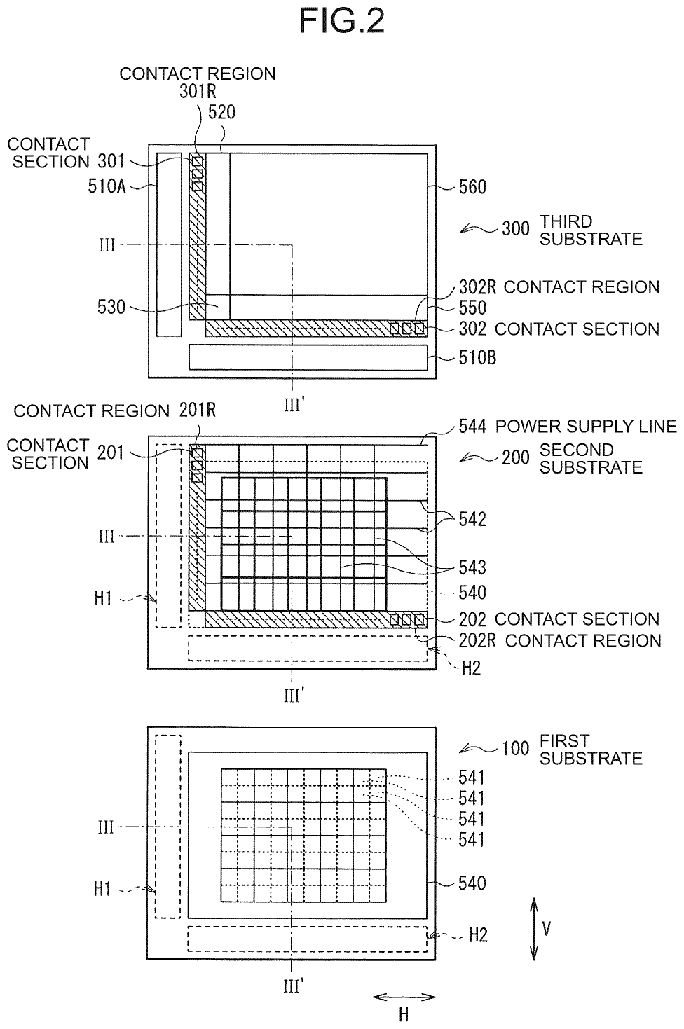

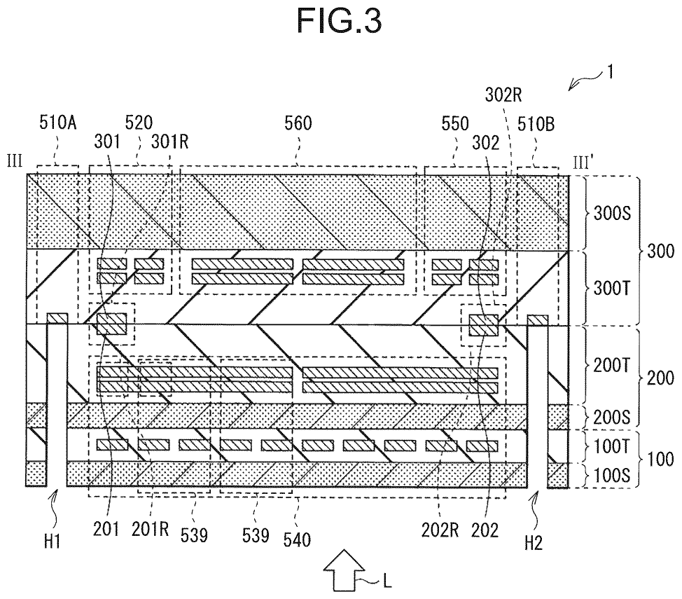

Next, an example of a schematic configuration of an imaging device 1 of a comparative example will be described with reference to FIGS. 2 and 3. FIG. 2 is a schematic plan view illustrating a schematic configuration of the imaging device 1 of the comparative example and is a diagram schematically illustrating a planar structure of each of a first semiconductor substrate 100, a second semiconductor substrate 200, and a third semiconductor substrate 300 of the imaging device 1 including the three semiconductor substrates (first semiconductor substrate 100, second semiconductor substrate 200, and third semiconductor substrate 300). FIG. 3 is a schematic diagram illustrating a cross-sectional structure taken along line III-III′ illustrated in FIG. 2. Note that, in this example, the comparative example means the imaging device 1 that have been repeatedly examined by the inventors before devising the embodiments of the present disclosure.

Specifically, it is based on the premise that the imaging device 1 has a three-dimensional structure configured by bonding three semiconductor substrates (the first semiconductor substrate 100, the second semiconductor substrate 200, and the third semiconductor substrate 300) illustrated in FIG. 2 and is, for example, a back-illuminated imaging device to which light is incident from the back surface (second surface) (light incident surface) side of the first semiconductor substrate 100 having photodiodes. The first semiconductor substrate 100 includes a semiconductor layer 100S and a wiring layer 100T. The second semiconductor substrate 200 includes a semiconductor layer 200S and a wiring layer 200T. The third semiconductor substrate 300 includes a semiconductor layer 300S and a wiring layer 300T. Herein, a combination of wiring included in each of the first semiconductor substrate 100, the second semiconductor substrate 200, and the third semiconductor substrate 300 and an interlayer insulating film around the wiring is referred to as a wiring layer (100T, 200T, or 300T) included in each of the semiconductor substrates (the first semiconductor substrate 100, the second semiconductor substrate 200, and the third semiconductor substrate 300) for convenience. As illustrated in FIG. 3, the first semiconductor substrate 100, the second semiconductor substrate 200, and the third semiconductor substrate 300 are stacked in this order, and the semiconductor layer 100S, the wiring layer 100T, the semiconductor layer 200S, the wiring layer 200T, the wiring layer 300T, and the semiconductor layer 300S are arranged in this order along the stacking direction. Specific configurations of the first semiconductor substrate 100, the second semiconductor substrate 200, and the third semiconductor substrate 300 will be described later. Note that an arrow illustrated in FIG. 3 indicates the incident direction of light L on the imaging device 1.

Specifically, the first semiconductor substrate 100 includes a plurality of pixels 541. Each of these pixels 541 includes a photodiode (PD) and a transfer transistor (TR). Furthermore, a pixel circuit is included in the second semiconductor substrate 200. The pixel circuit can read out charge generated in each of the photodiodes of the pixels 541 as a pixel signal via a transfer transistor or reset the photodiode. In addition to such a pixel circuit, the second semiconductor substrate 200 includes a plurality of row drive signal lines 542 extending in the row direction and a plurality of vertical signal lines 543 extending in the column direction. The second semiconductor substrate 200 further includes a power supply line 544 extending in the row direction.

The third semiconductor substrate 300 includes, for example, an input section 510A, a row drive section 520, a timing control section 530, a column signal processing section 550, an image signal processing section 560, and an output section 510B. The row drive section 520 is provided, for example, in a region where a part thereof overlaps the pixel array section 540 in the stacking direction of the first semiconductor substrate 100, the second semiconductor substrate 200, and the third semiconductor substrate 300 (hereinafter, simply referred to as a stacking direction). More specifically, the row drive section 520 is provided in a region overlapping the vicinity of an end of the pixel array section 540 in the H direction in the stacking direction (see FIG. 2). The column signal processing section 550 is provided, for example, in a region partially overlapping the pixel array section 540 in the stacking direction. More specifically, the column signal processing section 550 is provided in a region overlapping the vicinity of an end of the pixel array section 540 in the V direction in the stacking direction (see FIG. 2). Although not illustrated, the input section 510A and the output section 510B may be arranged in a portion other than the third semiconductor substrate 300 and, for example, may be arranged in the second semiconductor substrate 200. Alternatively, the input section 510A and the output section 510B may be provided on the back surface (light incident surface) side of the first semiconductor substrate 100. Note that a pixel circuit included in the second semiconductor substrate 200 may be referred to as a pixel transistor circuit, a pixel transistor group, a pixel transistor, a pixel readout circuit, or a readout circuit as another name. In the present specification, the term “pixel circuit” is used.

Furthermore, the first semiconductor substrate 100 and the second semiconductor substrate 200 are electrically connected by, for example, a through electrode. In addition, as illustrated in FIG. 3, the second semiconductor substrate 200 and the third semiconductor substrate 300 are electrically connected via, for example, contact sections 201, 202, 301, and 302. More specifically, the contact sections 201 and 202 are included in the second semiconductor substrate 200, and the contact sections 301 and 302 are included in the third semiconductor substrate 300. The contact section 201 of the second semiconductor substrate 200 is in contact with the contact section 301 of the third semiconductor substrate 300, and the contact section 202 of the second semiconductor substrate 200 is in contact with the contact section 302 of the third semiconductor substrate 300. The second semiconductor substrate 200 includes a contact region 201R in which a plurality of contact sections 201 is included and a contact region 202R in which a plurality of contact sections 202 is included. The third semiconductor substrate 300 includes a contact region 301R in which a plurality of contact sections 301 is included and a contact region 302R in which a plurality of contact sections 302 is included. The contact regions 201R and 301R are included between the pixel array section 540 and the row drive section 520 in the stacking direction (see FIG. 3). In other words, the contact regions 201R and 301R are included, for example, in a region where the row drive section 520 (third semiconductor substrate 300) and the pixel array section 540 (second semiconductor substrate 200) overlap in the stacking direction or in a vicinity region thereof. The contact regions 201R and 301R are arranged, for example, at an end in the H direction in such a region (see FIG. 2). In the third semiconductor substrate 300, for example, the contact region 301R is included at a position overlapping a part of the row drive section 520, specifically, an end of the row drive section 520 in the H direction (see FIGS. 2 and 3). The contact sections 201 and 301 connect, for example, the row drive section 520 included in the third semiconductor substrate 300 and the row drive signal lines 542 included in the second semiconductor substrate 200. For example, the contact sections 201 and 301 may connect the input section 510A included in the third semiconductor substrate 300 to the power supply line 544 and a reference potential line (VSS). The contact regions 202R and 302R are included between the pixel array section 540 and the column signal processing section 550 in the stacking direction (see FIG. 3). In other words, the contact regions 202R and 302R are included, for example, in a region where the column signal processing section 550 (third semiconductor substrate 300) and the pixel array section 540 (second semiconductor substrate 200) overlap in the stacking direction or in a vicinity region thereof. The contact regions 202R and 302R are arranged, for example, at an end in the V direction in such a region (see FIG. 2). In the third semiconductor substrate 300, for example, the contact region 301R is included at a position overlapping a part of the column signal processing section 550, specifically, an end of the column signal processing section 550 in the V direction (see FIGS. 2 and 3). For example, the contact sections 202 and 302 secure electrical connection in order to transmit a pixel signal (a signal corresponding to the amount of charge generated as a result of photoelectric conversion in the photodiode) output from each of the plurality of pixels 541 to the column signal processing section 550 included in the third semiconductor substrate 300.

As illustrated in FIG. 3, the first semiconductor substrate 100, the second semiconductor substrate 200, and the third semiconductor substrate 300 are electrically connected via the wiring layers 100T, 200T, and 300T. For example, the imaging device 1 includes electrical connection sections that electrically connect the second semiconductor substrate 200 and the third semiconductor substrate 300. Specifically, the contact sections 201, 202, 301, and 302 are formed by electrodes made of a conductive material. The conductive material is, for example, a metal material such as copper (Cu), aluminum (Al), or gold (Au). The contact regions 201R, 202R, 301R, and 302R electrically connect the second semiconductor substrate 200 and the third semiconductor substrate 300 by directly bonding pieces of wiring formed as electrodes, for example, and enable signal input and/or output between the second semiconductor substrate 200 and the third semiconductor substrate 300.

The electrical connection sections that electrically connect the second semiconductor substrate 200 and the third semiconductor substrate 300 can be included at desired locations. For example, as described as the contact regions 201R, 202R, 301R, and 302R with reference to FIG. 2, the electrical connection sections may be included in a region overlapping the pixel array section 540 in the stacking direction. Alternatively, the electrical connection sections may be included in a region not overlapping the pixel array section 540 in the stacking direction. Specifically, the electrical connection sections may be included in a region overlapping a peripheral portion disposed outside the pixel array section 540 in the stacking direction.

Furthermore, referring back to FIG. 3 and continuing the description, the first semiconductor substrate 100 and the second semiconductor substrate 200 each include, for example, connection holes H1 and H2. As illustrated in FIG. 3, the connection holes H1 and H2 each penetrate the first semiconductor substrate 100 and the second semiconductor substrate 200. The connection holes H1 and H2 are included outside the pixel array section 540 (or a portion overlapping the pixel array section 540) (see FIG. 2). For example, the connection hole H1 is disposed outside the pixel array section 540 in the H direction, and the connection hole H2 is disposed outside the pixel array section 540 in the V direction. For example, the connection hole H1 reaches the input section 510A included in the third semiconductor substrate 300, and the connection hole H2 reaches the output section 510B included in the third semiconductor substrate 300. The connection holes H1 and H2 may be hollow or partially or entirely contain a conductive material. For example, the conductive material may be formed on a side wall of the connection holes H1 and H2.

Furthermore, in the imaging device 1, for example, a bonding wire may be connected to electrodes provided on the bottom surfaces of the connection holes H1 and H2 formed as the input section 510A and/or the output section 510B. Alternatively, the electrode may be connected with the conductive material provided in the connection holes H1 and H2.

Note that, in the example illustrated in FIG. 3, the input section 510A and the output section 510B are included in the third semiconductor substrate 300; however, embodiments of the present disclosure are not limited thereto. For example, by sending signals of the third semiconductor substrate 300 to the second semiconductor substrate 200 via the wiring layers 200T and 300T, the input section 510A and/or the output section 510B can be included in the second semiconductor substrate 200. Similarly, by sending signals of the second semiconductor substrate 200 to the first semiconductor substrate 100 via the wiring layers 100T and 200T, the input section 510A and/or the output section 510B can be included in the first semiconductor substrate 100.

### 1.3 Background and Overview of Embodiments of Present Disclosure

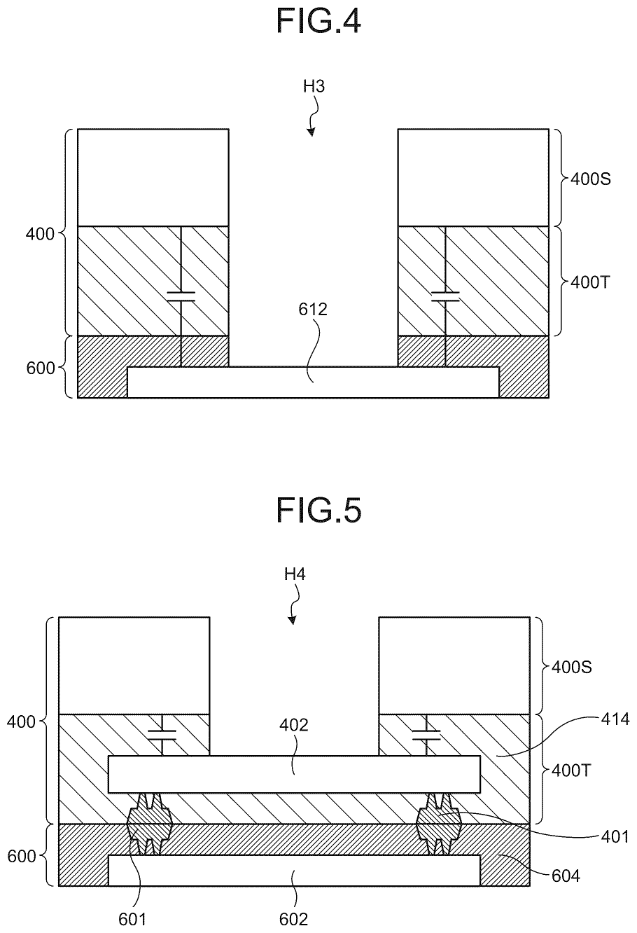

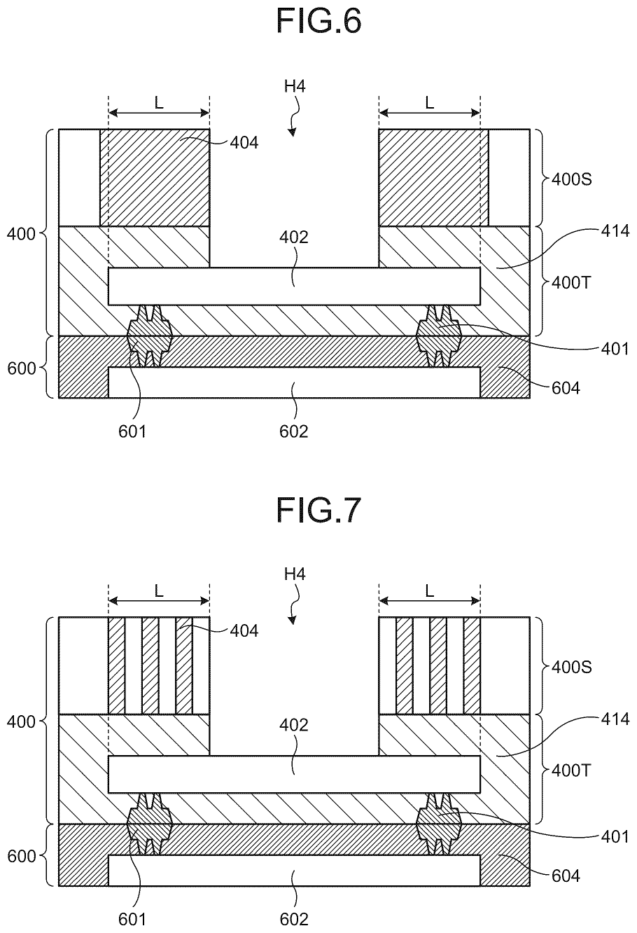

Next, details of the background which led the present inventors to create the embodiments of the present disclosure will be described with reference to FIGS. 4 to 8 on the basis of the configuration of the imaging device 1 described above. FIGS. 4 and 5 are schematic diagrams illustrating the main part of a cross-sectional structure of the imaging device 1 of the comparative example, and FIGS. 6 to 8 are schematic diagrams illustrating the main part of a cross-sectional structure of an embodiment of the present disclosure. Note that FIGS. 4 to 8 correspond to a cross section of the imaging device 1 in which substrates are stacked, cut along the stacking direction of the substrates. Note that the comparative example herein means the imaging device 1 that have been repeatedly examined by the inventors before devising the embodiments of the present disclosure as mentioned earlier.

As illustrated in FIG. 4, in the imaging device 1 according to the comparative example, two semiconductor substrates 400 and 600 are stacked. The semiconductor substrate 400 corresponds to the first semiconductor substrate 100 described above or the stacked layers of the first semiconductor substrate 100 and the second semiconductor substrate 200 (see FIG. 3), and for example, a plurality of pixels 541, a pixel circuit, and the like are included in the semiconductor substrate 400. More specifically, as illustrated in FIG. 4, the semiconductor substrate 400 includes stacked layers of a semiconductor layer 400S and a wiring layer 400T (more specifically, the wiring layer 400T includes a wiring layer and an insulating film covering the wiring layer).

In addition, the semiconductor substrate 600 corresponds to the third semiconductor substrate 300 described above (see FIG. 3) and includes logic circuits such as an input section 510A, a row drive section 520, a timing control section 530, a column signal processing section 550, an image signal processing section 560, and an output section 510B. Furthermore, in order to make the imaging device 1 compact, the semiconductor substrates 400 and 600 are stacked on each other and directly bonded by the contact sections 202 and 302 and the like (see FIG. 3) made of metal such as copper (Cu) described above. Note that, in FIG. 4, the contact sections 202 and 302 and the like are not illustrated.

Then, as illustrated in FIG. 4, the semiconductor substrate 600 includes a pad portion (electrode) 612 for electrical connection with the outside of the imaging device 1. The pad portion 612 is made of a conductive material such as metal and, for example, a bonding wire or the like is electrically connected to a surface thereof. Specifically, a surface of the central region of the pad portion 612 is exposed by an opening H3 included in such a manner as to penetrate the semiconductor substrate 400 and to penetrate a part of the semiconductor substrate 600 along the stacking direction of the semiconductor substrate 400 and the semiconductor substrate 600.

Note that the pad portion 612 is located, for example, in an outer peripheral region of the imaging device 1 in a plan view of the imaging device 1 including stacked layers the two semiconductor substrates 400 and 600 (namely, in a case where the imaging device 1 is viewed from above the semiconductor substrate 400). Note that, in the comparative examples and the embodiments of the present disclosure described later, the pad portions 612 and 402 (see FIG. 6) are not limited to being located in an outer peripheral region of the imaging device 1.

Furthermore, the semiconductor substrate 600 includes the pad portion 612, wiring (not illustrated), and the like, which are formed of a metal film such as aluminum (Al) having a predetermined film thickness (for example, a film thickness greater than or equal to 0.1 μm. In addition, in the semiconductor substrate 600, the metal film is covered with an insulating film. Moreover, in a case where the metal film is thick, it is conceivable to stack an insulating film by a method such as high density plasma (HDP)-chemical vapor deposition (CVD) in order to secure the coverage of the insulating film with respect to the metal film. Specifically, even if a step formed by the metal film is large, since it is possible to form an insulating film capable of entering the step portion and covering the top surface and the side surface of the metal film. Therefore, HDP-CVD or the like is used when an insulating film covering a metal film having a large film thickness is formed.

However, the insulating film formed by HDP-CVD may contain a large amount of hydrogen (H), and such hydrogen may diffuse from the insulating film into the semiconductor substrate 600 to cause fluctuation of the threshold value (Vth) of transistors included in the semiconductor substrate 600. In such a case, in order to suppress the threshold fluctuation, it is also conceivable to perform ion implantation to adjust the threshold value to a desired value. However, depending on a transistor structure (for example, in a case of transistors having a Fin-type field effect transistor (FET) structure or the like), it may be difficult to adjust the threshold value by ion implantation.

Therefore, the present inventors conceived of an idea of including the pad portion 612 on the semiconductor substrate 400 side as illustrated in FIG. 5. Specifically, in the comparative example illustrated in FIG. 5, two semiconductor substrates 400 and 600 are stacked similarly to the example of FIG. 4. The semiconductor substrates 400 and 600 are stacked and directly bonded to each other by contact sections 401 and 601 made of metal such as copper (Cu).

In the comparative example illustrated in FIG. 5, the semiconductor substrate 600 including the logic circuits includes a wiring layer 602 and an insulating film 604 covering the wiring layer 602 and does not include the pad portion 612. Furthermore, the semiconductor substrate 400 including a plurality of pixels 541, a pixel circuit, and others includes stacked layers of a semiconductor layer 400S and a wiring layer 400T.

Moreover, in the comparative example illustrated in FIG. 5, instead of the pad portion 612 included in the semiconductor substrate 600, a pad portion (electrode) 402 for electrical connection with the outside of the imaging device 1 is included in the semiconductor substrate 400. The pad portion 402 is made of a conductive material such as a metal film, and, for example, a bonding wire or the like is electrically connected to a surface thereof. A surface of the central region of the pad portion 402 is exposed by an opening H4 included in such a manner as to penetrate the semiconductor layer 400S and to penetrate a part of the wiring layer 400T (specifically, an insulating film 414 on the pad portion 402) along the stacking direction of the semiconductor substrate 400 and the semiconductor substrate 600. On the other hand, surfaces of the peripheral region of the pad portion 402 are covered with the insulating film 414 constituting a part of the wiring layer 400T. This is because the pad portion 402 is provided such that the area of the pad portion 402 is larger than that of the opening H4 in consideration of positional deviation and the like at the time of forming the opening H4 in manufacturing (for example, mass production) of the imaging device 1. Therefore, in the comparative example illustrated in FIG. 5, the peripheral region of the pad portion 402 faces the semiconductor layer 400S via the insulating film 414 without the surface being exposed by the opening H4.

Therefore, in the comparative example illustrated in FIG. 5, since the peripheral region of the pad portion 402 is a conductor facing the semiconductor layer 400S via the insulating film 414, a parasitic capacitance may be generated here. Furthermore, also in the comparative example illustrated in FIG. 4, similarly to the comparative example illustrated in FIG. 5, the pad portion 612 is provided such that the area of the pad portion 612 is larger than that of the opening H3 in consideration of positional deviation and the like in manufacturing of the imaging device 1. Also in FIG. 4, since the peripheral region of the pad portion 612 is a conductor facing the semiconductor layer 400S via the wiring layer 400T including the insulating film, a parasitic capacitance may also occur here. However, in the comparative example of FIG. 5, the distance between the pad portion 402 and the semiconductor layer 400S is short, and, specifically, the distance is short as compared with the distance between the pad portion 612 and the semiconductor layer 400S in the comparative example of FIG. 4. Therefore, the parasitic capacitance in the comparative example of FIG. 5 is larger than the parasitic capacitance in the comparative example of FIG. 4.

Furthermore, since a delay, waveform distortion, or the like occurs in a signal transmitted via the pad portion 402 due to the parasitic capacitance, the present inventors considered that it is preferable to reduce the parasitic capacitance as much as possible. Therefore, the parasitic capacitance can be reduced by reducing the area of the region where the pad portion 402 and the semiconductor layer 400S face each other, in order to reduce the parasitic capacitance, the present inventors conceived of including an insulating film 404 in the semiconductor layer 400S facing a peripheral region L of the pad portion 402 (see FIG. 6) and created an embodiment of the present disclosure.

Specifically, in the embodiment according to the present disclosure created by the present inventors, as illustrated in FIG. 6, an imaging device (semiconductor device) 1 includes two semiconductor substrates (first substrate) 400 and (second substrate) 600 that are directly bonded by contact sections (bonding electrodes) 401 and 601 made of metal such as copper (Cu) and stacked on each other. The semiconductor substrate 600 including logic circuits includes a wiring layer 602 and an insulating film 604 covering the wiring layer 602. Furthermore, the semiconductor substrate 400 including a plurality of pixels 541, a pixel circuit, and others includes stacked layers of a semiconductor layer 400S and a wiring layer 400T.

In the embodiment of the present disclosure, the wiring layer 400T includes a pad portion (electrode) 402 for electrical connection to the outside of the imaging device 1. The pad portion 402 is made of a conductive material such as a metal film and is electrically connected with a bonding wire or the like. Furthermore, a surface of the central region (first region) of the pad portion 402 is exposed by an opening H4 included in such a manner as to penetrate the semiconductor layer 400S and to penetrate a part of the wiring layer 400T (specifically, an insulating film 414 on the pad portion 402) along the stacking direction of the semiconductor substrate 400 and the semiconductor substrate 600.

Furthermore, in the embodiment of the present disclosure, as illustrated in FIG. 6, the insulating film 404 is included in the semiconductor layer 400S facing the peripheral region (second region) L of the pad portion 402 which is not exposed by the opening H4. In the embodiment of the present disclosure, the parasitic capacitance can be reduced by including the insulating film 404 in the semiconductor layer 400S facing the peripheral region L of the pad portion 402 and reducing the area of the peripheral region L where the pad portion 402 and the semiconductor layer 400S face each other.

More specifically, in the embodiment of the present disclosure, as illustrated in FIG. 6, the insulating film 404 is included in the entire semiconductor layer 400S facing the peripheral region (second region) L of the pad portion 402 not exposed by the opening H4. Furthermore, in the embodiment of the present disclosure, as illustrated in FIG. 6, the insulating film 404 may be included in such a manner as to extend in a direction opposite to the opening H4 with respect to the semiconductor layer 400S facing the peripheral region L in consideration of positional deviation and the like in manufacturing of the imaging device 1.

Meanwhile, as illustrated in FIG. 6, in the case where the insulating film 404 is included in a wide range of the semiconductor layer 400S, it is conceivable that a longer time is required for the step of forming the insulating film 404. Specifically, the insulating film 404 can be formed by forming a groove in the semiconductor layer 400S and embedding an insulating material in the groove. Therefore, in the case where the insulating film 404 is included in a wide range of the semiconductor layer 400S, the insulating material is embedded in the wide groove, and thus a longer time is required for forming the insulating film 404. Therefore, in another embodiment of the present disclosure, the insulating film 404 may be included in a part of the semiconductor layer 400S facing the peripheral region (second region) L of the pad portion 402 that is not exposed by the opening H4.

Specifically, in another embodiment of the present disclosure, as illustrated in FIG. 7, a plurality of insulating films 404 is included in the semiconductor layer 400S facing the peripheral region (second region) L of the pad portion 402 which is not exposed by the opening H4. Specifically, the insulating films 404 are alternately included with semiconductor layers 400S interposed therebetween. Since each of the insulating films 404 is formed by embedding an insulating material in a narrow groove in this manner, the time required for the step of forming the plurality of insulating films 404 can be shortened.

Note that, in the embodiment of the present disclosure, in order to avoid an increase in time required for the step of forming the insulating film 404 while reducing the parasitic capacitance, it is preferable to provide the plurality of insulating films 404 such that the total volume of the plurality of insulating films 404 is greater than or equal to ½ of the volume of a part of the semiconductor layer 400S facing the peripheral region (second region) L of the pad portion 402 that is not exposed by the opening H4.

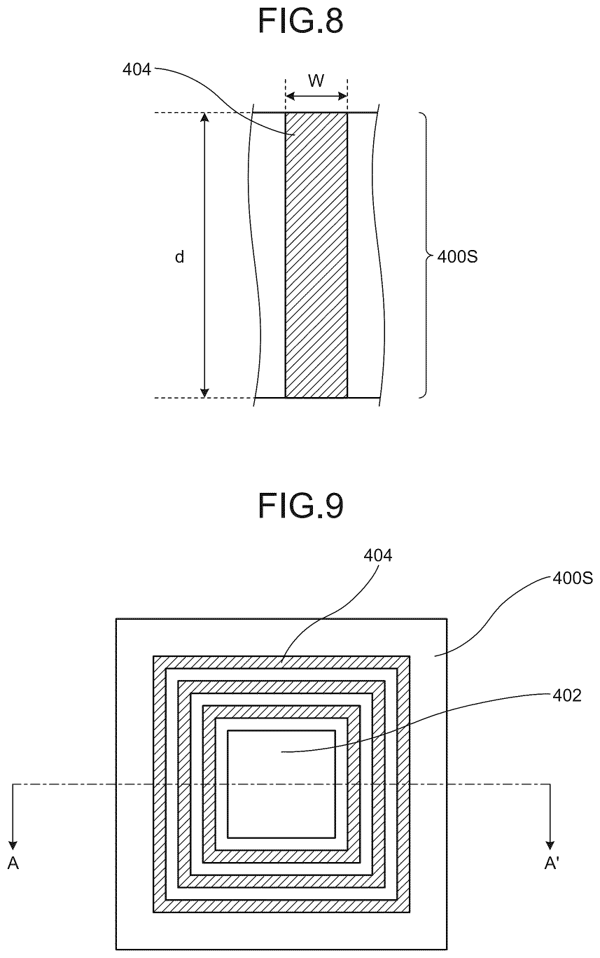

Furthermore, in the embodiment of the present disclosure, as illustrated in FIG. 8 which is an enlarged view of one of the plurality of insulating films 404 illustrated in FIG. 7, the relationship between a length (film thickness) d of an insulating film 404 along the stacking direction and a width W thereof along a direction orthogonal to the stacking direction preferably satisfies W/2<d. This makes it possible to avoid an increase in the time required for the step of forming the insulating film 404 while reducing the parasitic capacitance. Hereinafter, details of such embodiments of the present disclosure will be sequentially described.

Note that, in the following, embodiments in which the embodiment of the present disclosure is applied to an imaging device will be described; however, the embodiment of the present disclosure is not limited to being applied to an imaging device and can be applied to semiconductor devices in general. Furthermore, in the following, embodiments in which the embodiment of the present disclosure is applied to an imaging device (semiconductor device) having a stacked structure of a plurality of semiconductor substrates will be described. However, the embodiment of the present disclosure is not limited to be applied to an imaging device (semiconductor device) having a stacked structure of a plurality of semiconductor substrates and can be applied to semiconductor devices in general which do not having a stacked structure of semiconductor substrates.

### 2. First Embodiment

First, a first embodiment of the present disclosure will be described with reference to FIGS. 7 and 9. FIG. 9 is a schematic diagram illustrating the main part of a planar structure of the first embodiment of the disclosure. Specifically, FIG. 9 corresponds to a planar structure when the imaging device 1 in which the semiconductor substrates 400 and 600 are stacked is viewed from above, and a cross section of the imaging device 1 taken along line A-A′ illustrated in FIG. 9 corresponds to FIG. 7.

Specifically, as illustrated in FIG. 7, the imaging device (semiconductor device) 1 according to the present embodiment includes two semiconductor substrates (first substrate) 400 and (second substrate) 600 that are directly bonded by contact sections (bonding electrodes) 401 and 601 made of metal such as copper (Cu) and are stacked on each other. The semiconductor substrate 600 including logic circuits includes a wiring layer 602 and an insulating film 604 covering the wiring layer 602. Furthermore, the semiconductor substrate 400 including a plurality of pixels (imaging elements) 541, a pixel circuit, and others is formed by stacking a semiconductor layer 400S and a wiring layer 400T.

In the embodiment of the present disclosure, the wiring layer 400T includes a pad portion (electrode) 402 for electrical connection to the outside of the imaging device 1. The pad portion 402 is made of a conductive material such as a metal film and is electrically connected with a bonding wire or the like. Furthermore, a surface of the central region (first region) of the pad portion 402 is exposed by an opening H4 included in such a manner as to penetrate the semiconductor layer 400S and to penetrate a part of the wiring layer 400T (specifically, an insulating film 414 on the pad portion 402) along the stacking direction of the semiconductor substrate 400 and the semiconductor substrate 600.

Furthermore, in the embodiment of the present disclosure, as illustrated in FIG. 7, a plurality of insulating films 404 is included in the semiconductor layer 400S facing the peripheral region (second region) L of the pad portion 402 which is not exposed by the opening H4. In the present embodiment, the width of the peripheral region L can be, for example, about several micrometers. In the cross section, the insulating films 404 each have a rectangular cross section and are alternately included with the semiconductor layer 400S interposed therebetween. Specifically, in FIG. 7, three insulating films 404 are included on each of the right side and the left side with the opening H4 interposed therebetween. The width of each insulating film 404 and an interval between insulating films 404 can be, for example, within a range of about 0.1 μm or more to 1.5 μm or less. Note that, in the present embodiment, the cross section of an insulating film 404 is not limited to a rectangular shape and may have a trapezoidal shape spreading upward in FIG. 7 or spreading downward in FIG. 7. Alternatively, in the present embodiment, the cross section of an insulating film 404 may have a shape obtained by joining two trapezoids with either their upper bases or lower bases joined together. Furthermore, in the present embodiment, as long as the insulation between the semiconductor layer 400S and wires or the like connected with the pad portion 402 can be maintained and the strength of the opening H4 can be maintained high, the number of the insulating films 404 included on the right side and the left side with the opening H4 interposed therebetween is not limited to three.

Furthermore, in the present embodiment, some of the plurality of insulating films 404 may be included in such a manner as to extend in a direction on the opposite side to the opening H4 with respect to the semiconductor layer 400S facing the peripheral region L.

Furthermore, the insulating film 404 can be formed of one or more materials selected from a group consisting of a silicon oxide (SiO₂), a silicon nitride (Si₃N₄), a silicon oxynitride (SiON), a silicon carbide (SiC), a silicon carbonitride (SiCN), an organic insulating material, a metal oxide, a metal oxynitride, and a low dielectric constant material (such as SiOC, SiOF, SiOCH, SiOCH, hydrogen silsesquioxane, or methyl silsesquioxane).

Furthermore, in the present embodiment, as illustrated in FIG. 9, the plurality of insulating films 404 has a rectangular frame shape in a plan view and are included in such a manner as to triply surround the pad portion 402 exposed by the opening H4. Note that the length of one side of the rectangular pad portion 402 can be, for example, about several tens of micrometers to several hundreds of micrometers. Furthermore, in the present embodiment, the plurality of insulating films 404 is not limited to being included in such a manner as to triply surround the pad portion 402 exposed by the opening H4 but is only required to be included in such a manner as to surround the pad portion 402 with one or a plurality of insulating films. Furthermore, in the present embodiment, the widths of the plurality of insulating films 404 in a plan view are not limited to being substantially the same and may be different from each other.

Furthermore, in the present embodiment, the shape of the opening H4 in a plan view is not limited to a rectangular shape (square or rectangular) and may be a substantially circular shape or a rectangular shape having rounded vertices. In such a case, the shape of each of the insulating films 404 in a plan view may also be a substantially circular frame shape (ring shape) or a rectangular frame shape having rounded vertices.

As described above, in the present embodiment, as illustrated in FIGS. 7 and 9, the plurality of insulating films 404 is included in the semiconductor layer 400S facing the peripheral region (second region) L of the pad portion 402 which is not exposed by the opening H4. As a result, in the present embodiment, it is possible to avoid requiring more time for the step of forming the insulating films 404 while the parasitic capacitance is reduced.

### 3. Second Embodiment

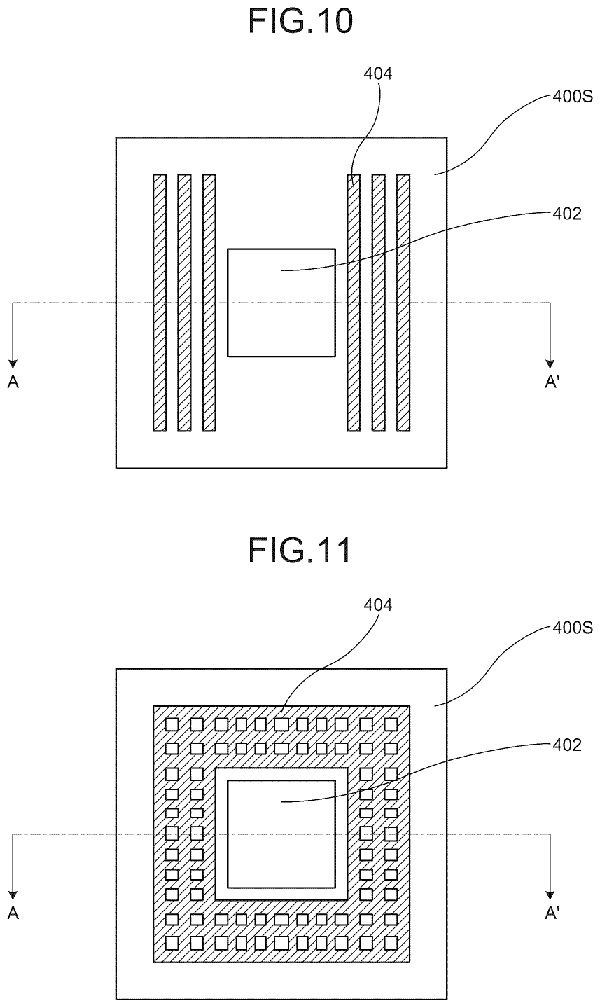

Next, a second embodiment of the present disclosure will be described with reference to FIG. 10. FIG. 10 is a schematic diagram illustrating the main part of a planar structure of the second embodiment of the disclosure. Specifically, FIG. 10 corresponds to a planar structure when the imaging device 1 in which the semiconductor substrates 400 and 600 are stacked is viewed from above, and a cross section of the imaging device 1 taken along line A-A′ illustrated in FIG. 10 corresponds to FIG. 7.

In the present embodiment, as illustrated in FIG. 10, a plurality of insulating films 404 have a rectangular shape in a plan view and are included in such a manner as to extend along sides of the opening H4 extending in the longitudinal direction in FIG. 10. Note that, in the present embodiment, the plurality of insulating films 404 is not limited to being included in such a manner as to extend along the sides of the opening H4 extending in the longitudinal direction in FIG. 10 and may be included in such a manner as to extend along sides of the opening H4 extending in the lateral direction in FIG. 10.

Furthermore, in the present embodiment, the widths of the plurality of insulating films 404 in a plan view are not limited to being substantially the same and may be different from each other.

Furthermore, in the present embodiment, the shape of each of the insulating films 404 in a plan view is not limited to the rectangular shape and may be an elliptical shape or a rectangular shape having rounded vertices.

Furthermore, in the present embodiment, the plurality of insulating films 404 is not limited to the three insulating films 404 included on each of the right side and the left side (or upper and lower sides) with the opening H4 interposed therebetween, and it is only required that one or a plurality of insulating films 404 be included on each of the right side and the left side (or upper and lower sides) with the opening H4 interposed therebetween. Furthermore, in the present embodiment, different numbers of insulating films 404 may be included on each of the right side and the left side (or upper and lower sides) with the opening H4 interposed therebetween.

As described above, in the present embodiment, as illustrated in FIG. 10, the plurality of insulating films 404 is included in the semiconductor layer 400S facing the peripheral region (second region) L of the pad portion 402 which is not exposed by the opening H4. As a result, in the present embodiment, it is possible to avoid requiring more time for the step of forming the insulating films 404 while the parasitic capacitance is reduced.

### 4. Third Embodiment

Next, a third embodiment of the present disclosure will be described with reference to FIG. 11. FIG. 11 is a schematic diagram illustrating the main part of a planar structure of the third embodiment of the disclosure. Specifically, FIG. 11 corresponds to a planar structure when the imaging device 1 in which the semiconductor substrates 400 and 600 are stacked is viewed from above, and a cross section of the imaging device 1 taken along line A-A′ illustrated in FIG. 11 corresponds to FIG. 7.

In the present embodiment, as illustrated in FIG. 11, an insulating film 404 is included in a lattice shape around the pad portion 402 exposed by the opening H4 in a plan view. Note that, in the present embodiment, the width of the insulating film 404 in a plan view is not limited to being substantially the same over the entire region and may be different.

Furthermore, in the present embodiment, the shape of the insulating film 404 in the plan view is not limited to the shape obtained by combining a plurality of rectangles in a lattice shape and may be a shape obtained by combining ellipses or rectangles having rounded vertices in a lattice shape.

As described above, in the present embodiment, as illustrated in FIG. 11, the insulating film 404 having the lattice shape in the plan view is included in the semiconductor layer 400S facing the peripheral region (second region) L of the pad portion 402 which is not exposed by the opening H4. As a result, in the present embodiment, it is possible to avoid requiring more time for the step of forming the insulating films 404 while the parasitic capacitance is reduced.

### 5. Fourth Embodiment

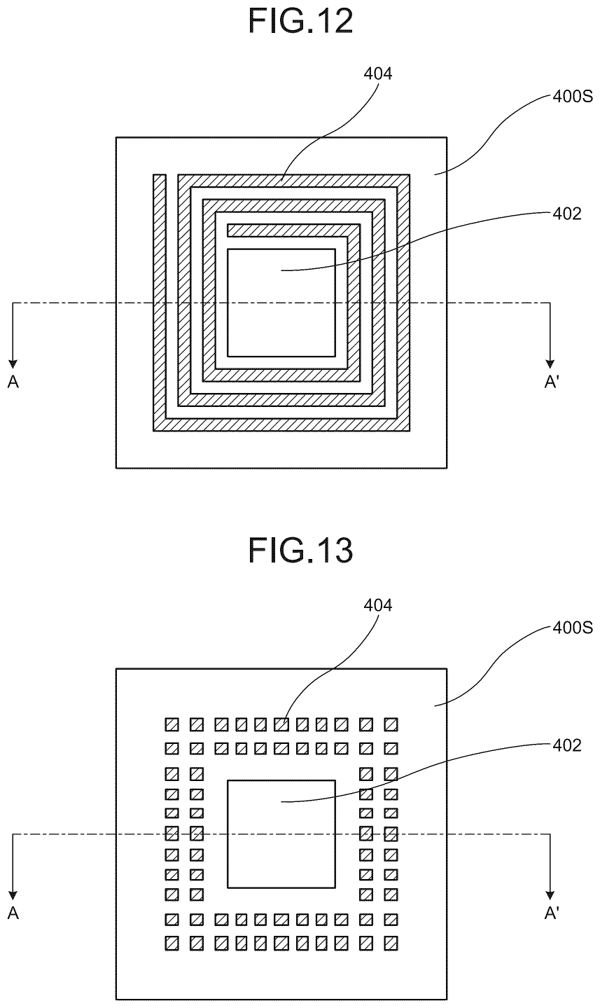

Next, a fourth embodiment of the present disclosure will be described with reference to FIG. 12. FIG. 12 is a schematic diagram illustrating the main part of a planar structure of the fourth embodiment of the disclosure. Specifically, FIG. 12 corresponds to a planar structure when the imaging device 1 in which the semiconductor substrates 400 and 600 are stacked is viewed from above, and a cross section of the imaging device 1 taken along line A-A′ illustrated in FIG. 12 corresponds to FIG. 7.

In the present embodiment, as illustrated in FIG. 12, the insulating film 404 is included in a spiral shape around the pad portion 402 exposed by the opening H4 in a plan view. Note that, in the present embodiment, the width of the insulating film 404 in a plan view is not limited to being substantially the same over the entire region and may be different.

Furthermore, in the present embodiment, the shape of the insulating film 404 in the plan view is not limited to a shape in which a plurality of rectangles is formed into a spiral shape and may be a shape in which ellipses are formed into a spiral shape.

As described above, in the present embodiment, as illustrated in FIG. 12, the insulating film 404 having a narrow width is included in the semiconductor layer 400S facing the peripheral region (second region) L of the pad portion 402 which is not exposed by the opening H4. As a result, in the present embodiment, it is possible to avoid requiring more time for the step of forming the insulating films 404 while the parasitic capacitance is reduced.

### 6. Fifth Embodiment

Next, a fifth embodiment of the present disclosure will be described with reference to FIG. 13. FIG. 13 is a schematic diagram illustrating the main part of a planar structure of the fifth embodiment of the disclosure. Specifically, FIG. 13 corresponds to a planar structure when the imaging device 1 in which the semiconductor substrates 400 and 600 are stacked is viewed from above, and a cross section of the imaging device 1 taken along line A-A′ illustrated in FIG. 13 corresponds to FIG. 7.

In the present embodiment, as illustrated in FIG. 13, a plurality of insulating films 404 has a rectangular shape in a plan view and is included in an island shape (doted shape) around the pad portion 402 exposed by the opening H4. Note that, in the present embodiment, the shape of each of the insulating films 404 in the plan view is not limited to the rectangular shape and may be an elliptical shape or a rectangular shape having rounded vertices. Furthermore, in the present embodiment, the sizes of the respective insulating films 404 in the plan view are not limited to being substantially the same and may be different.

As described above, in the present embodiment, as illustrated in FIG. 13, small insulating films 404 are included in island shapes in the semiconductor layer 400S facing the peripheral region (second region) L of the pad portion 402 not exposed by the opening H4. As a result, in the present embodiment, it is possible to avoid requiring more time for the step of forming the insulating films 404 while the parasitic capacitance is reduced.

### 7. Sixth Embodiment

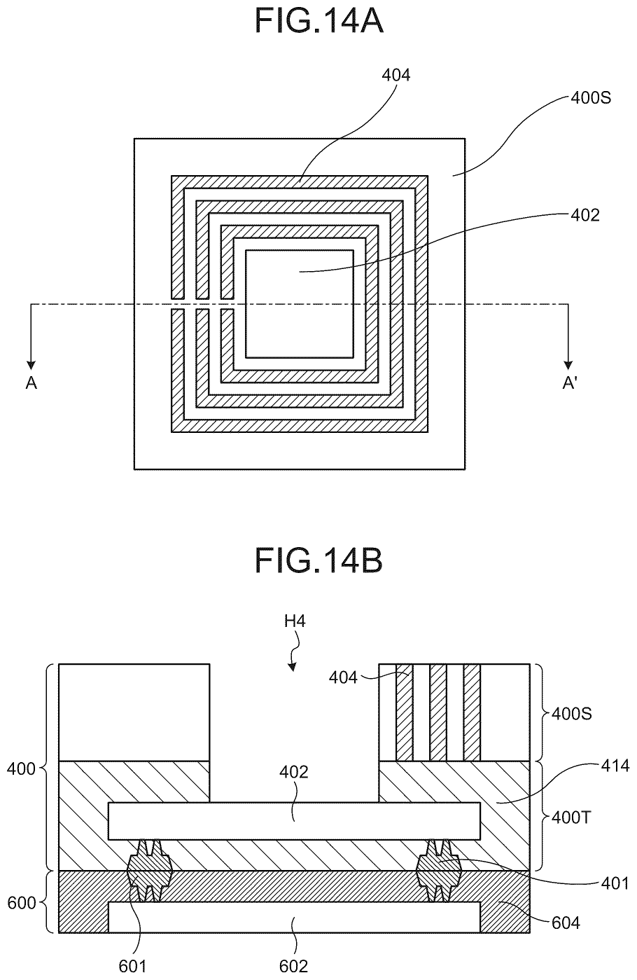

Next, a sixth embodiment of the present disclosure will be described with reference to FIGS. 14A and 14B. FIG. 14A is a schematic diagram illustrating the main part of a planar structure of the sixth embodiment of the present disclosure, and FIG. 14B is a schematic diagram illustrating the main part of a cross-sectional structure of the sixth embodiment of the present disclosure. Specifically, FIG. 14A corresponds to a planar structure when the imaging device 1 in which the semiconductor substrates 400 and 600 are stacked is viewed from above, and a cross section of the imaging device 1 taken along line A-A′ illustrated in FIG. 14A corresponds to FIG. 14B.

In the present embodiment, as illustrated in FIG. 14A, a part of each insulating film 404 having a rectangular frame shape is missing as compared with the first embodiment illustrated in FIG. 9. Therefore, in FIG. 14B illustrating a cross section of the imaging device 1 taken along line A-A′ illustrated in FIG. 14A, the insulating films 404 are located on one side and no insulating film 404 is located on the other side with the opening H4 interposed therebetween.

Note that, also in the present embodiment, the widths of the plurality of insulating films 404 in a plan view are not limited to being substantially the same and may be different from each other. Furthermore, in the present embodiment, the shape of each of the insulating films 404 in a plan view is not limited to a rectangular shape nor a polygonal shape and may be an elliptical shape or a rectangle or a polygonal shape having rounded vertices.

As described above, in the present embodiment, as illustrated in FIGS. 14A and 14B, the plurality of insulating films 404 is included in the semiconductor layer 400S facing the peripheral region (second region) L of the pad portion 402 which is not exposed by the opening H4. As a result, in the present embodiment, it is possible to avoid requiring more time for the step of forming the insulating films 404 while the parasitic capacitance is reduced.

### 8. Seventh Embodiment

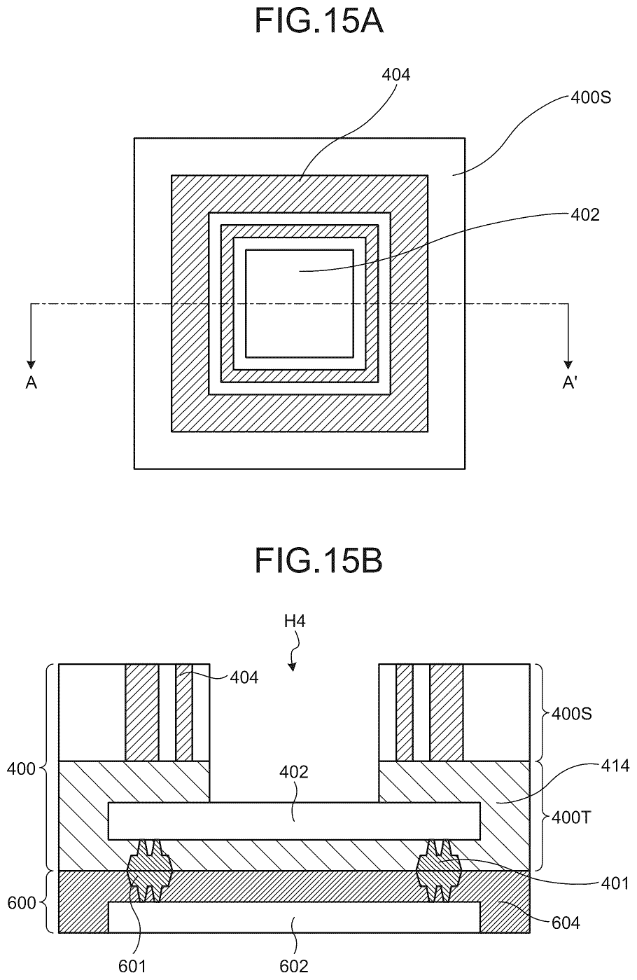

Next, a sixth embodiment of the present disclosure will be described with reference to FIGS. 15A and 15B. FIG. 15A is a schematic diagram illustrating the main part of a planar structure of the seventh embodiment of the present disclosure, and FIG. 15B is a schematic diagram illustrating the main part of a cross-sectional structure of the seventh embodiment of the present disclosure. Specifically, FIG. 15A corresponds to a planar structure when the imaging device 1 in which the semiconductor substrates 400 and 600 are stacked is viewed from above, and a cross section of the imaging device 1 taken along line A-A′ illustrated in FIG. 15A corresponds to FIG. 15B.

In the present embodiment, as illustrated in FIG. 15A, widths of the insulating films 404 having a rectangular frame shape are different from each other as compared with the first embodiment illustrated in FIG. 9. Therefore, also in FIG. 15B illustrating a cross section of the imaging device 1 taken along line A-A′ illustrated in FIG. 15A, the widths of the plurality of insulating films 404 are different from each other.

Note that, also in the present embodiment, the shape of each of the insulating films 404 in the plan view is not limited to the rectangular shape and may be an elliptical shape or a rectangular shape having rounded vertices.

As described above, in the present embodiment, as illustrated in FIGS. 15A and 15B, the plurality of insulating films 404 having different widths is included in the semiconductor layer 400S facing the peripheral region (second region) L of the pad portion 402 which is not exposed by the opening H4. As a result, in the present embodiment, it is possible to avoid requiring more time for the step of forming the insulating films 404 while the parasitic capacitance is reduced.

### 9. Eighth Embodiment

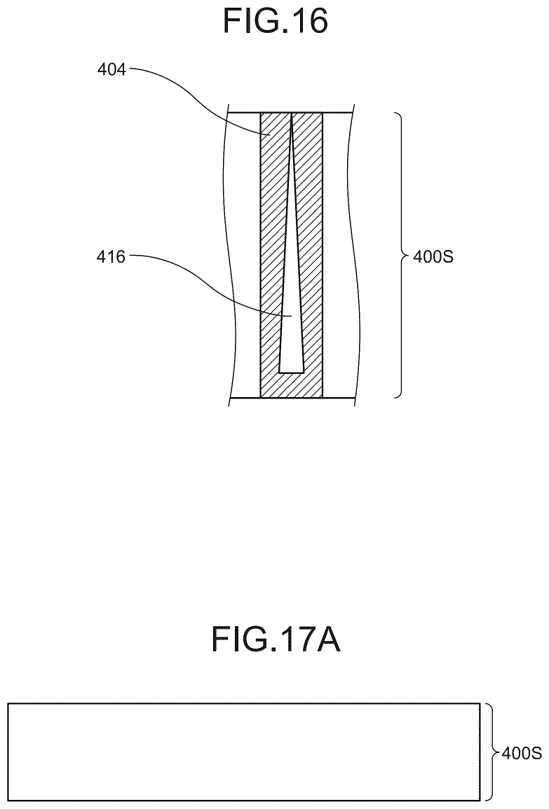

Next, an eighth embodiment of the present disclosure will be described with reference to FIG. 16. FIG. 16 is a schematic diagram illustrating the main part of a cross-sectional structure of the eighth embodiment of the present disclosure and is, specifically, an enlarged view of one insulating film 404 among the plurality of insulating films 404 illustrated in FIG. 7.

In the embodiment of the present disclosure described above, the insulating films 404 are alternately included with the semiconductor layer 400S interposed therebetween. Therefore, a parasitic capacitance may be generated between pieces of the semiconductor layer 400S adjacent to each other with an insulating film 404 interposed therebetween.

Therefore, in the present embodiment, as illustrated in FIG. 16, a hollow hole (air gap) 416 may be included in the insulating film 404. Since the air in the hollow hole has a dielectric constant lower than that of an insulating material, including the hollow hole 416 in the insulating film 404 can reduce the parasitic capacitance generated between pieces of the semiconductor layer 400S with the insulating film 404 interposed therebetween. Note that the hollow hole 416 in the insulating film 404 can be formed, for example, by stacking the insulating film 404 by CVD using tetra ethoxy silane (TEOS). In addition, as described above, each insulating film 404 is formed by embedding an insulating material in a groove included in the semiconductor layer 400S. However, according to the present embodiment, it is not necessary to completely fill the groove with the insulating material, and thus it is possible to avoid requiring more time for the step of forming the insulating film 404.

As described above, in the present embodiment, as illustrated in FIG. 16, by forming the hollow hole 416 in the insulating films 404, it is possible to avoid requiring more time for the step of forming the insulating films 404 while the parasitic capacitance is reduced which is generated between pieces of the semiconductor layer 400S with the insulating films 404 interposed therebetween.

### 10. Ninth Embodiment

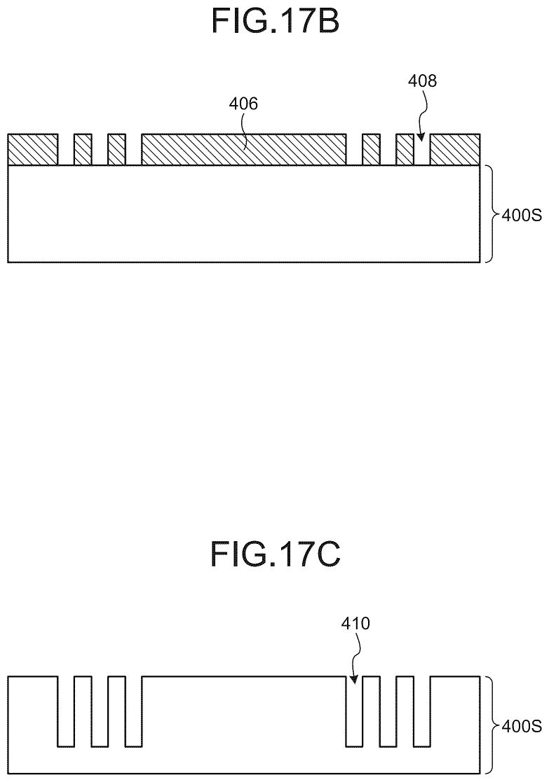

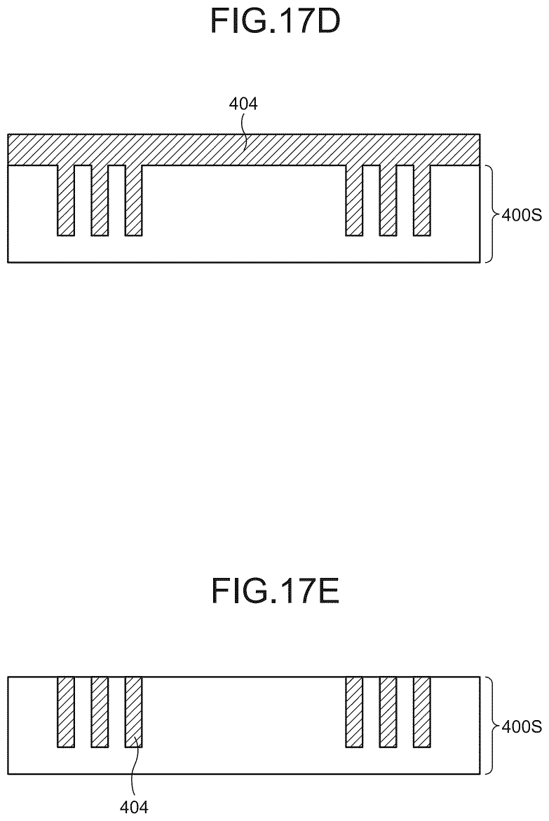

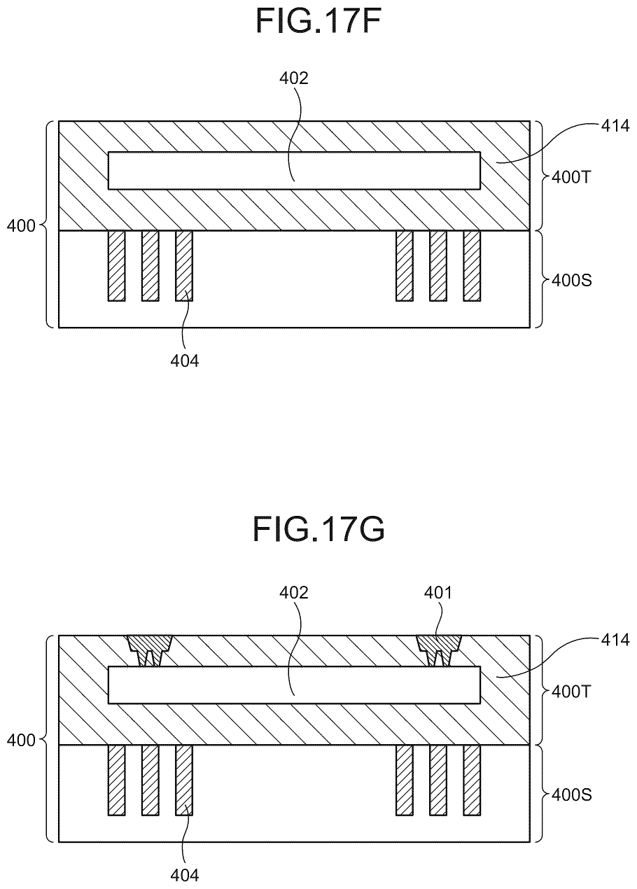

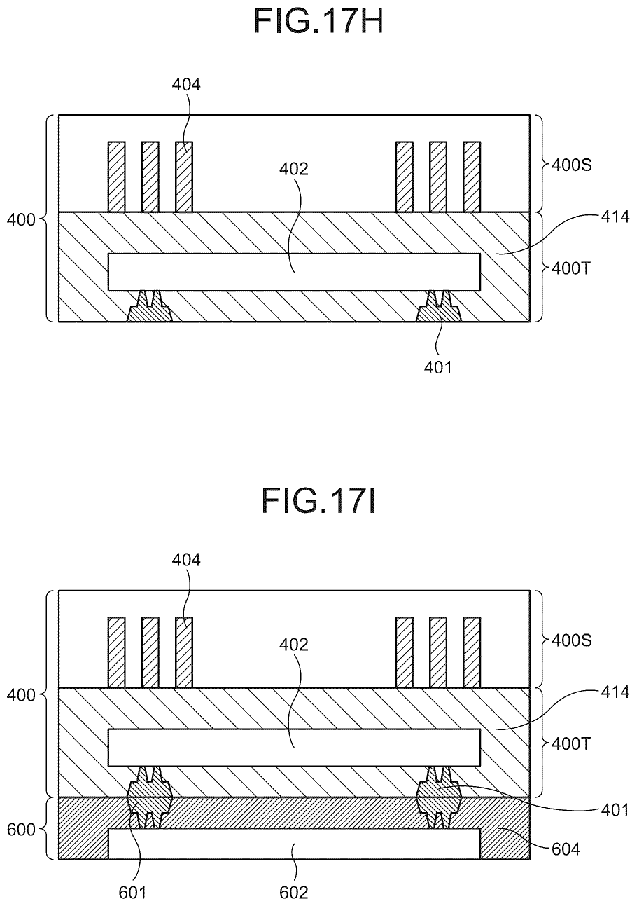

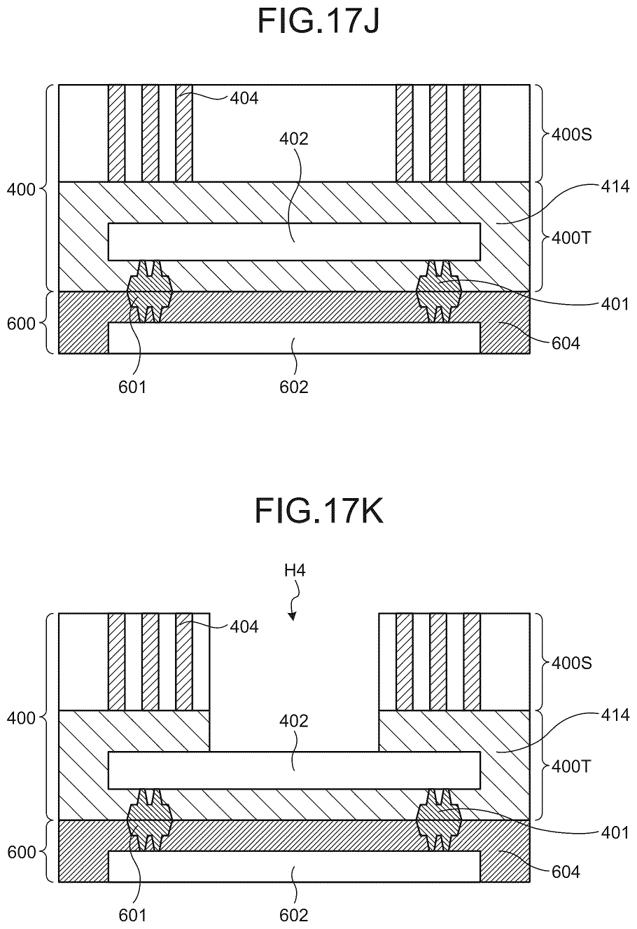

Next, a manufacturing method of the imaging device 1 according to the first embodiment will be described with reference to FIGS. 17A to 17K. FIGS. 17A to 17K are explanatory diagrams illustrating a part of the manufacturing method of the imaging device 1 according to the first embodiment of the present disclosure and are cross-sectional views corresponding to FIG. 7.

First, a semiconductor substrate to be the semiconductor layer 400S as illustrated in FIG. 17A is prepared, and a mask 406 having a pattern (openings 408) is formed on the semiconductor layer 400S as illustrated in FIG. 17B. Next, by etching the semiconductor layer 400S along the openings 408 of the mask 406 and removing the mask 406 from the semiconductor layer 400S, the semiconductor layer 400S having grooves 410 as illustrated in FIG. 17C can be formed.

Next, as illustrated in FIG. 17D, an insulating film 404 is formed on the semiconductor layer 400S in such a manner as to fill the grooves 410. Furthermore, the insulating film 404 spilling over from the grooves 410 is removed by etching, chemical mechanical polishing (CMP), or the like, whereby a form as illustrated in FIG. 17E can be obtained.

Then, as illustrated in FIG. 17F, the insulating film 414 to be a part of the wiring layer 400T and the pad portion 402 are formed on the semiconductor layer 400S, thereby obtaining the semiconductor substrate 400. Furthermore, as illustrated in FIG. 17G, contact sections 401 for bonding with the semiconductor substrate 600 are formed on the top surface side of the insulating film 414, and as illustrated in FIG. 17H, the semiconductor substrate 400 is turned upside down.

Furthermore, as illustrated in FIG. 17I, the semiconductor substrate 600 on which the contact sections 601, the wiring layer 602, and others are formed is prepared, and the semiconductor substrates 400 and 600 are stacked and joined in such a manner that the contact sections 601 and 401 face each other. Next, as illustrated in FIG. 17J, the semiconductor layer 400S is thinned in such a manner that the top surfaces of the insulating films 404 are exposed. Then, the opening H4 is formed in such a manner as to penetrate the semiconductor layer 400S and to penetrate a part of the wiring layer 400T (specifically, the insulating film 414 on the pad portion 402) along the stacking direction so that the central region of the pad portion 402 is exposed, whereby it is possible to obtain a form as illustrated in FIG. 17K.

### 11. Tenth Embodiment

### 11.1 Embodiment

As described earlier, in the comparative example illustrated in FIG. 5, the distance between the pad portion 402 and the semiconductor layer 400S is short, and the peripheral region of the pad portion 402 is a conductor facing the semiconductor layer 400S via the insulating film 414, and thus a parasitic capacitance may be generated here. Moreover, due to the parasitic capacitance, a delay, waveform distortion, or the like occurs in a signal transmitted via the pad portion 402. Therefore, in order to prevent occurrence of such a delay or the like, it is desired for the imaging device 1 to reduce the parasitic capacitance as much as possible.

Specifically, in a case where the parasitic capacitance is regarded as a parallel plate type capacitance, capacitance C of the parasitic capacitance is given by C=(ε×S)/d, where S is a surface area of each flat plate, d is a distance between flat plates, and ε is a dielectric constant of a region sandwiched between a pair of flat plates. Therefore, in order to reduce the capacitance C, first, it is conceivable to increase the distance d. However, in a case where the distance d is to be increased, the film thickness of the insulating film 414 is increased, or the number of stacked wires in the wiring layer 400T is increased, in which case an increase in the manufacturing cost is inevitable, and bonding to the pad portion 402 is difficult. Therefore, it is difficult to select a method of increasing the distance d in an attempt to reduce the capacitance C.

Alternatively, in order to reduce the capacitance C, it is conceivable to reduce the surface area S, namely, to reduce the area where the peripheral region L of the pad portion 402 and the semiconductor layer 400S face each other. However, since the area in which the peripheral region L of the pad portion 402 and the semiconductor layer 400S face each other is reduced, there is a concern about deterioration of yield or deterioration of reliability. Therefore, it is difficult to select a method of reducing the area S in an attempt to reduce the capacitance C.

Therefore, the present inventors have studied reducing the dielectric constant & in order to reduce the capacitance C of the parasitic capacitance. During intensive studies, the present inventors conceived of an idea of including an air gap containing air or the like having a low dielectric constant & in the wiring layer 400T between the peripheral region L of the pad portion 402 not exposed by the opening H4 and the semiconductor layer 400S facing the peripheral region L. Hereinafter, details of a tenth embodiment of the present disclosure, which is an embodiment including an air gap and created by the present inventors, will be described.

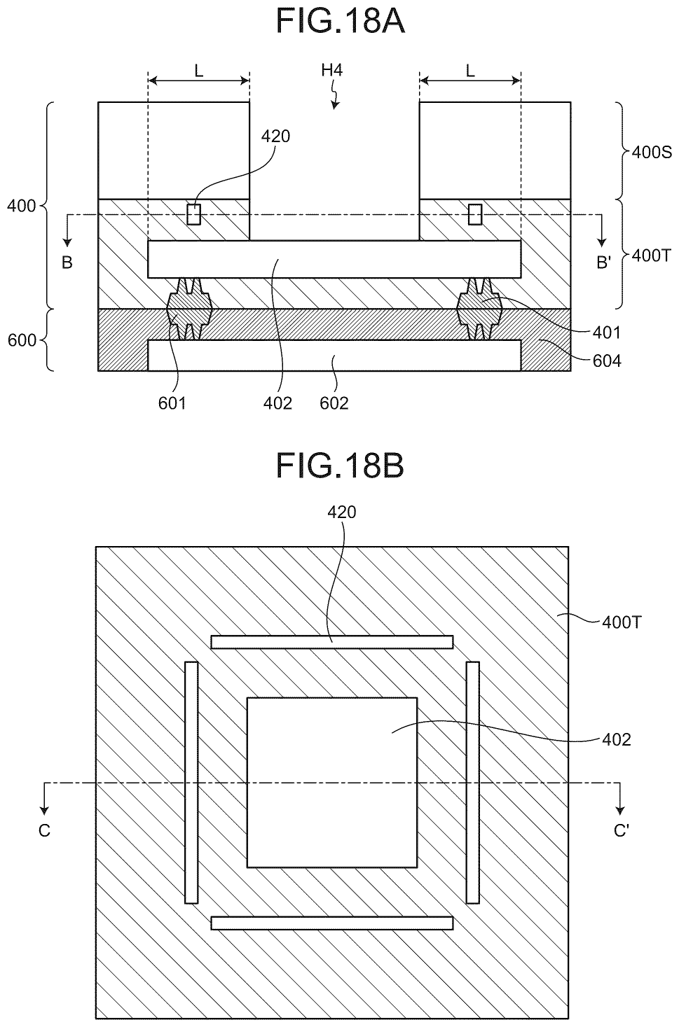

First, the tenth embodiment of the present disclosure will be described with reference to FIGS. 18A and 18B. FIG. 18A is a schematic diagram illustrating the main part of a cross-sectional structure of the present embodiment, and FIG. 18B is a schematic diagram illustrating the main part of a planar structure of the present embodiment. Specifically, FIG. 18A is a diagram illustrating a cross section taken along line C-C′ in FIG. 18B, and FIG. 18B is a diagram illustrating a plane taken along line B-B′ in FIG. 18A.

In the present embodiment, as illustrated in FIG. 18A, air gaps 420 are included in the wiring layer 400T between the peripheral region (second region) L of the pad portion 402 not exposed by the opening H4 and the semiconductor layer 400S facing the peripheral region L. The air gap 420 is filled with a gas such as air. As described above, the dielectric constant ε of air or the like is lower than that of the insulating film 414 included in the wiring layer 400T. Specifically, for example, the relative dielectric constant of silicon oxide (SiO₂) forming the insulating film 414 is 3.9, and the relative dielectric constant of air is 1.0. Therefore, by including the air gaps 420, the capacitance C of the parasitic capacitance that can be generated between the peripheral region L of the pad portion 402 and the semiconductor layer 400S facing the peripheral region L can be reduced. Alternatively, in the present embodiment, the air gaps 420 may be filled with a low dielectric material having a dielectric constant ε lower than that of the insulating films 414. In this case, the relative dielectric constant of the low dielectric material is at least smaller than 3.9 and, preferably, for example, around 2.6. However, in a case where the distance between the semiconductor layer 400S and the pad portion 402 and another wiring layer or between the semiconductor layer 400S and the pad portion 402 is short, the probability of occurrence of leakage is increased. Therefore, in the present embodiment, it is preferable to use the air gap 420 filled with a gas such as air in order to prevent such leakage.

In the present embodiment, as illustrated in FIG. 18B, the air gap 420 may be a plurality of rectangular spaces arranged in such a manner as to surround the opening H4 that exposes a part of the pad portion 402.

Specifically, the four spaces constituting the air gaps 420 are arranged respectively along the directions in which the four sides of the opening H4 extend and are included in such a manner as to be symmetric with respect to the opening H4 in a plan view.

As described above, in the present embodiment, the air gaps 420 are included in the wiring layer 400T between the peripheral region L of the pad portion 402 not exposed by the opening H4 and the semiconductor layer 400S facing the peripheral region L. According to the present embodiment, since the air or the like filled in the air gaps 420 has a dielectric constant ε lower than that of the insulating film 414, the capacitance C of the parasitic capacitance that can be generated between the peripheral region L of the pad portion 402 and the semiconductor layer 400S facing the peripheral region L can be reduced.

### 11.2 First Modification

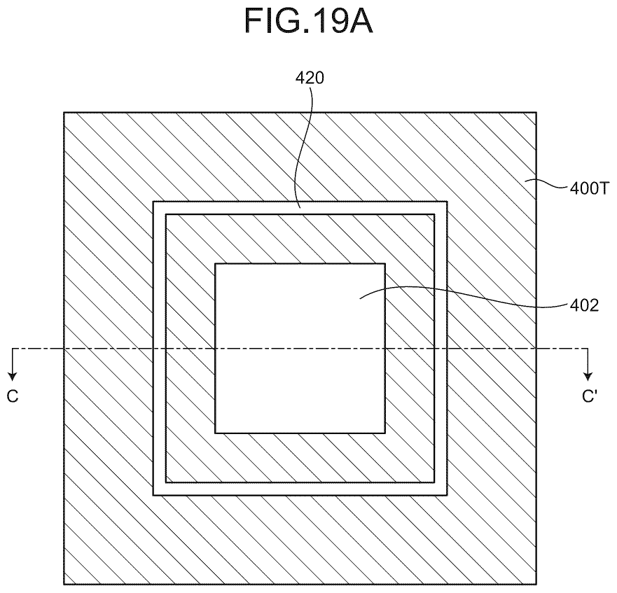

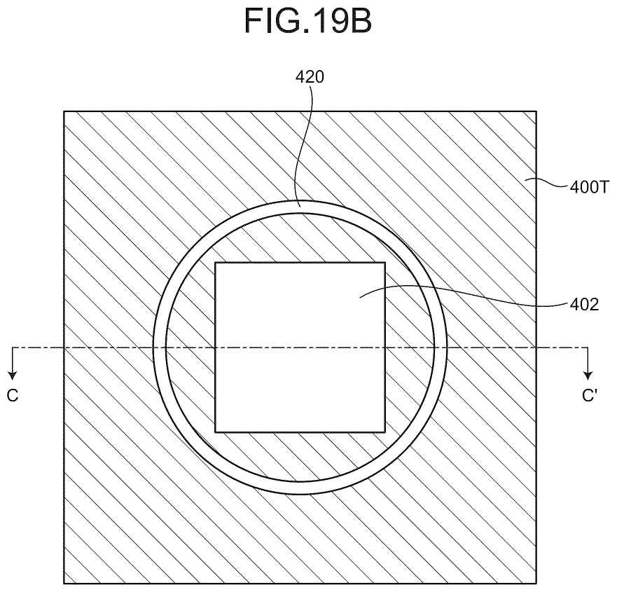

In addition, in the present embodiment, the structure of the air gaps 420 can be variously modified. Therefore, a first modification of the present embodiment will be described with reference to FIGS. 19A and 19B. FIG. 19A is a schematic diagram illustrating the main part of a planar structure of Modification 1-1 of the present embodiment, and FIG. 19B is a schematic diagram illustrating the main part of a planar structure of Modification 1-2 of the present embodiment, and these drawings correspond to FIG. 18B.

For example, in Modification 1-1, as illustrated in FIG. 19A, the air gap 420 is included in a rectangular frame shape in such a manner as to surround the opening H4 that exposes a part of the pad portion 402. In other words, in the present embodiment described above, the air gaps 420 are configured by the four rectangular spaces. Meanwhile, in the present modification, the four rectangular spaces are connected as an integrated space, namely, a single frame-shaped space is formed.

Alternatively, for example, in Modification 1-2 as illustrated in FIG. 19B, the air gap 420 is included in an annular shape in such a manner as to surround the opening H4 that exposes a part of the pad portion 402. Note that, in the present modification, the shape of the air gap 420 in a plan view is not limited to a rectangular frame shape or an annular shape and may be a polygonal frame shape, an elliptical annular shape, or the like.

### 11.3 Second Modification

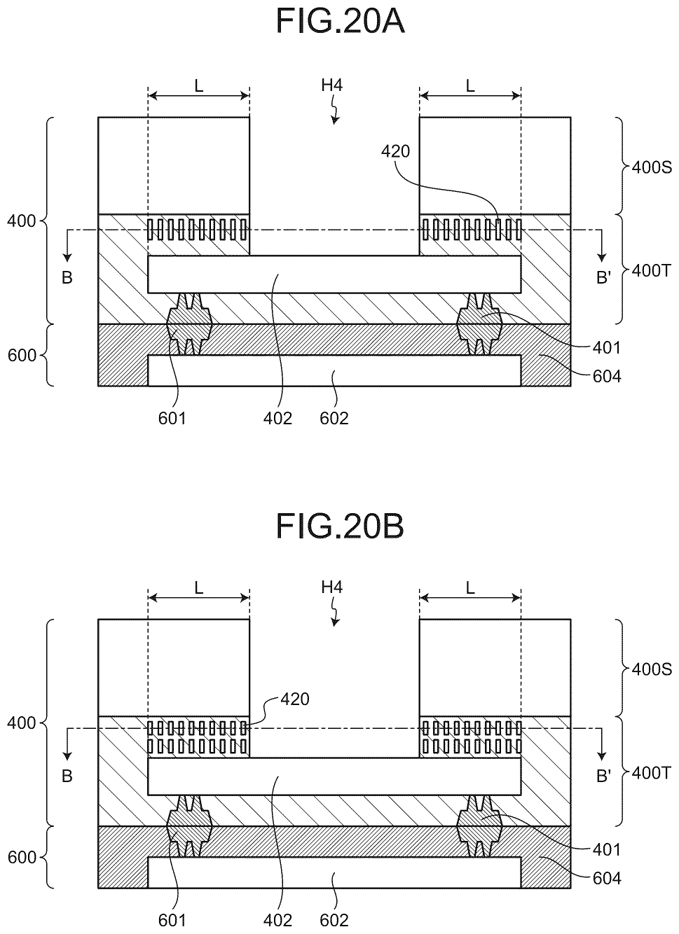

In the present embodiment, a plurality of air gaps 420 may be included. Therefore, a second modification of the embodiment will be described with reference to FIGS. 20A and 20B. FIG. 20A is a schematic diagram illustrating the main part of a cross-sectional structure of Modification 2-1 of the present embodiment, FIG. 20B is a schematic diagram illustrating the main part of a cross-sectional structure of Modification 2-2 of the present embodiment, and these diagrams correspond to FIG. 18A.

For example, in Modification 2-1, as illustrated in FIG. 20A, a plurality of air gaps 420 is included with the same height in the wiring layer 400T. Furthermore, for example, in Modification 2-2, as illustrated in FIG. 20B, a plurality of air gaps 420 is included with different heights in the wiring layer 400T.

Here, for example, a case where the length of the peripheral region L of the pad portion 402 is 3 μm, the distance between the peripheral region L and the semiconductor layer 400S facing the peripheral region L is 0.355 μm, and the insulating film 414 included in the wiring layer 400T is made of silicon oxide will be examined. In this case, in a case where one air gap 420 of 50 nm×100 nm is included in a plan view, it can be expected that the capacitance C of the parasitic capacitance generated in the pad portion 402 is reduced by about 0.75%. In addition, in a case where ten air gaps 420 of 50 nm×100 nm are included in a plan view, a reduction in the capacity of about 7.5% can be expected, and in a case where 120 air gaps 420 of 50 nm×100 nm are provided in such a manner as to overlay in the vertical direction, a reduction in the capacity of about 47% can be expected.

### 11.4 Third Modification

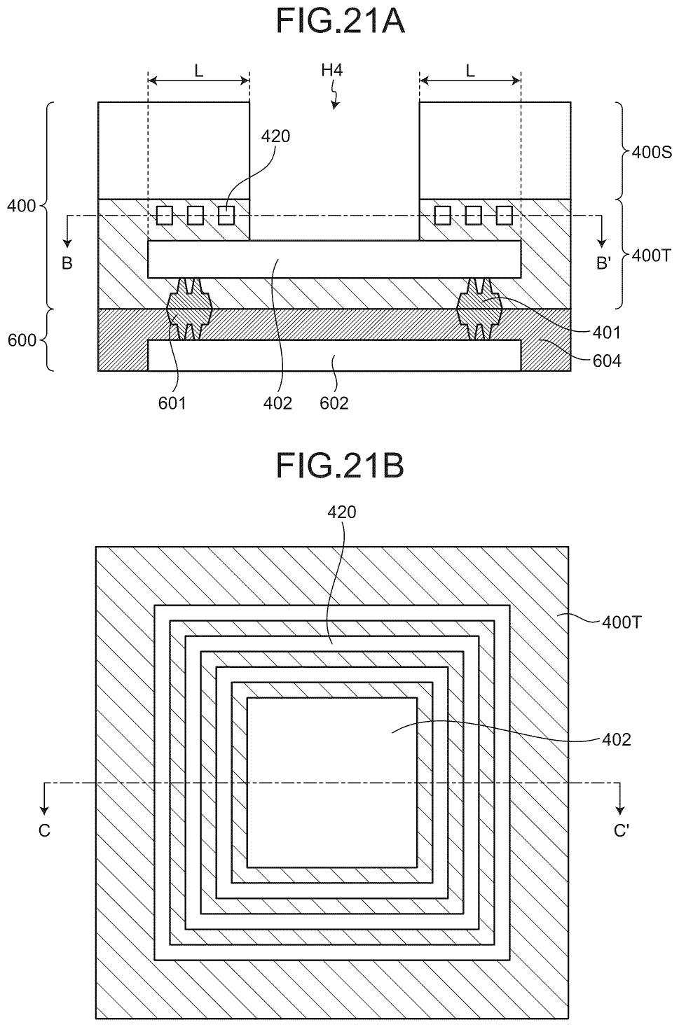

In the present embodiment, even in a case where a plurality of air gaps 420 is included, various modifications can be further made. Therefore, a third modification of the embodiment will be described with reference to FIGS. 21A and 21B. FIG. 21A is a schematic diagram illustrating the main part of a cross-sectional structure of Modification 3-1 of the present embodiment and corresponds to FIG. 18A. Likewise, FIG. 21B is a schematic diagram illustrating the main part of a planar structure of Modification 3-1 of the present embodiment and corresponds to FIG. 18B.

For example, in Modification 3-1, as illustrated in FIGS. 21A and 21B, each of the plurality of air gaps 420 is included in a rectangular frame shape in such a manner as to surround the opening H4.

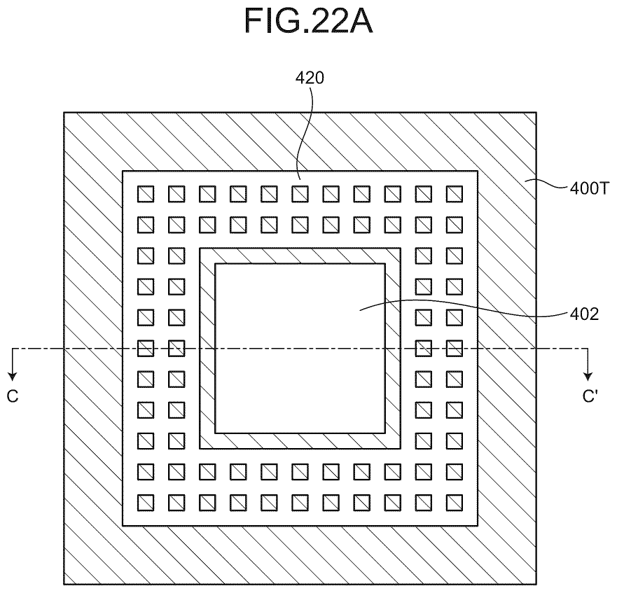

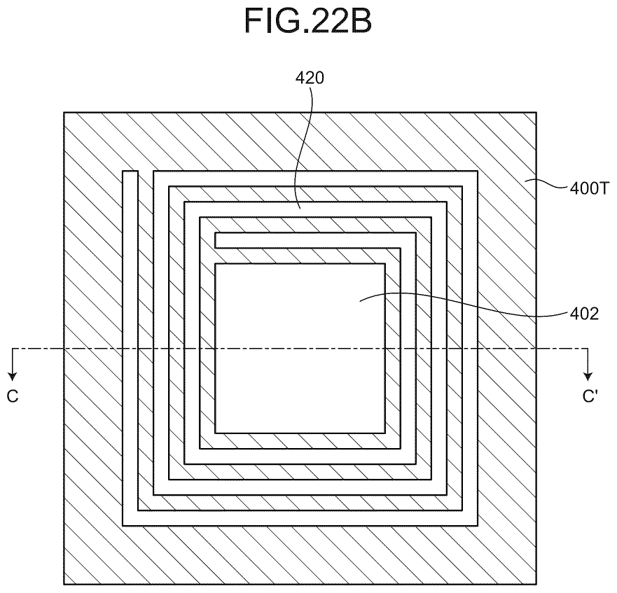

Furthermore, a planar structure having the same cross section as that in FIG. 21A can be further modified. Therefore, Modification 3-2 to Modification 3-4 will be described with reference to FIGS. 22A to 22C. FIG. 22A is a schematic diagram illustrating the main part of a planar structure of Modification 3-2 of the present embodiment, FIG. 22B is a schematic diagram illustrating the main part of a planar structure of Modification 3-3 of the present embodiment, and FIG. 22B is a schematic diagram illustrating the main part of a planar structure of Modification 3-4 of the present embodiment.

For example, in Modification 3-2, as illustrated in FIG. 22A, the plurality of rectangular air gaps 420 is connected to each other to form a lattice shape.

Furthermore, for example, in Modification 3-3, as illustrated in FIG. 22B, the plurality of rectangular air gaps 420 is connected to each other to form a spiral shape.

Furthermore, for example, in Modification 3-4, as illustrated in FIG. 22C, each of the plurality of air gaps 420 may have a rectangular island shape and be arranged in such a manner as to surround the opening H4.

### 11.5 Fourth Modification

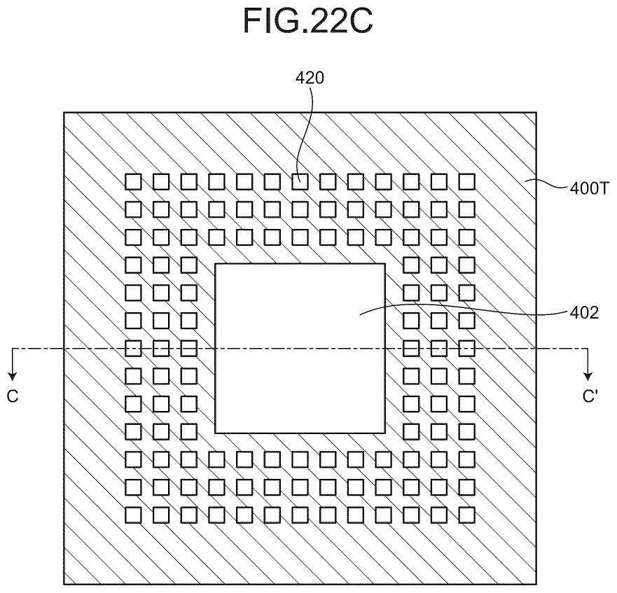

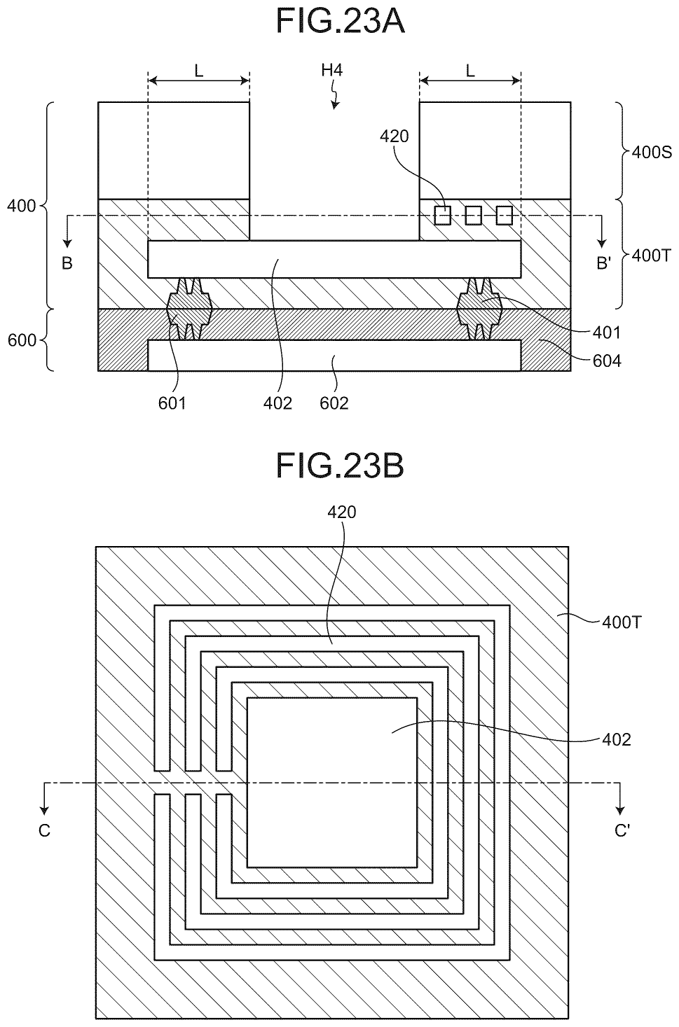

Furthermore, a further modification of the air gaps 420 will be described with reference to FIGS. 23A and 23B. FIG. 23A is a schematic diagram illustrating the main part of a cross-sectional structure of a fourth modification of the present embodiment and corresponds to FIG. 18A. Likewise, FIG. 23B is a schematic diagram illustrating the main part of a planar structure of the fourth modification of the present embodiment and corresponds to FIG. 18B.

As illustrated in FIGS. 23A and 23B, in the present fourth modification, a part of each of the air gaps 420 is missing as compared with Modification 3-1 illustrated in FIGS. 21A and 21B.

### 11.6 Fifth Modification

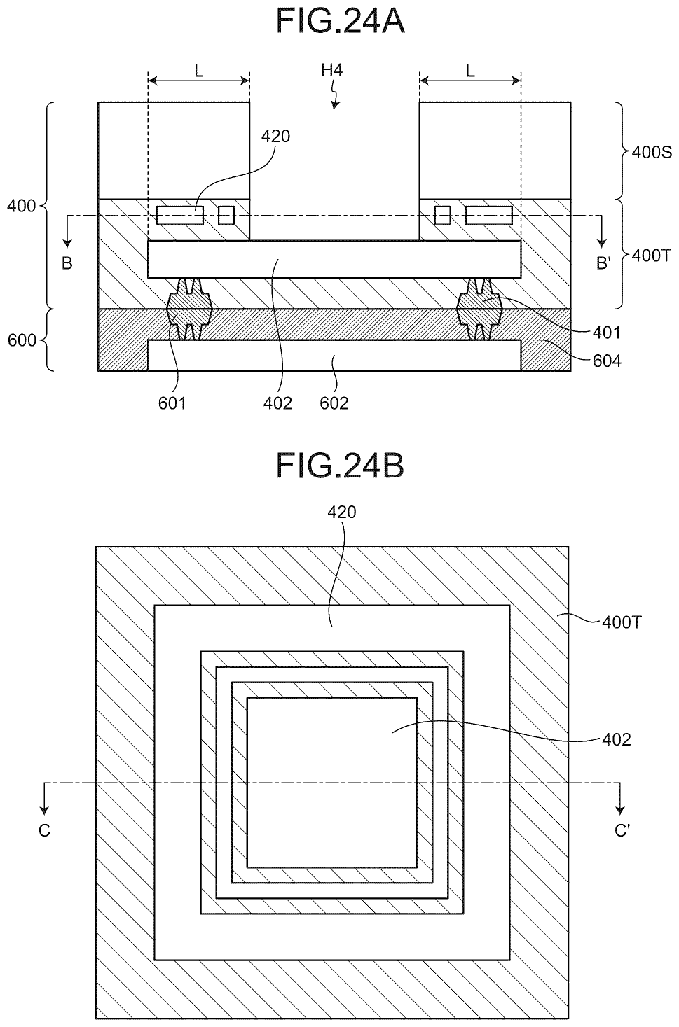

In the present embodiment, the plurality of air gaps 420 is not limited to having the same width. Therefore, a fifth modification will be described with reference to FIGS. 24A and 24B. FIG. 24A is a schematic diagram illustrating the main part of a cross-sectional structure of the fifth modification of the present embodiment and corresponds to FIG. 18A. Likewise, FIG. 24B is a schematic diagram illustrating the main part of a planar structure of the fifth modification of the present embodiment and corresponds to FIG. 18B.

For example, in the fifth modification, as illustrated in FIGS. 24A and 24B, a plurality of air gaps 420 each has a different width. Specifically, in the example illustrated in FIGS. 24A and 24B, an air gap 420 disposed on the inner side (near the pad portion 402) has a narrow width, and an air gap 420 disposed on the outer side (far from the pad portion 402) has a wide width. Note that, in the present modification, the air gap 420 disposed on the inner side may have a wide width, and the air gap 420 disposed on the outer side may have a narrow width.

### 11.7 Sixth Modification

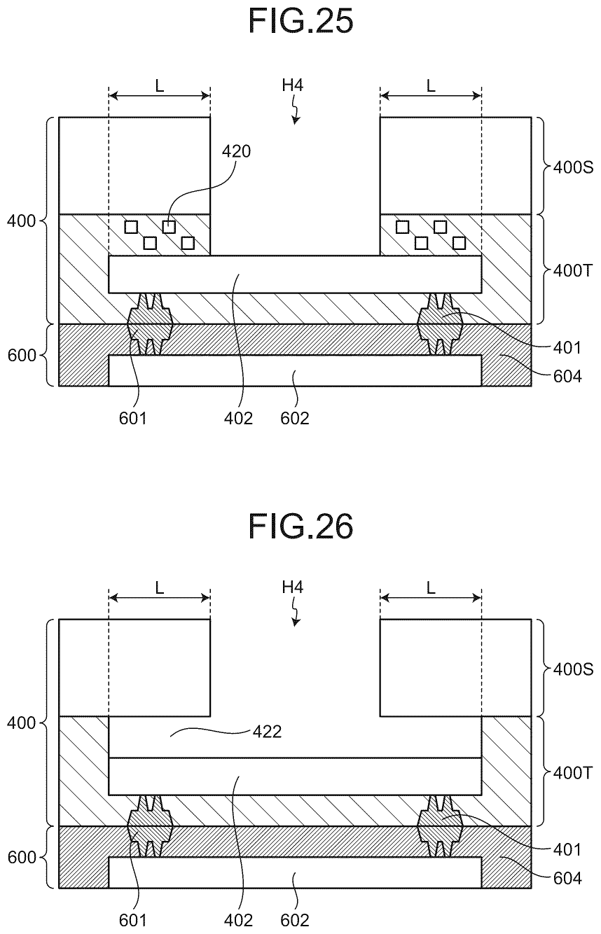

In the present embodiment, a plurality of air gaps 420 is not limited to be included uniformly. Therefore, a sixth modification will be described with reference to FIG. 25. FIG. 25 is a schematic diagram illustrating the main part of a cross-sectional structure of the sixth modification of the present embodiment and corresponds to FIG. 18A.

For example, in Modification 6, as illustrated in FIG. 25, the plurality of air gaps 420 may be included in a zigzag lattice shape or randomly in the wiring layer 400T and is not particularly limited.

### 11.8 Seventh Modification

Furthermore, in the present embodiment, the air gap 420 is not limited to being included in the insulating film 414 included in the wiring layer 400T. Therefore, a seventh modification will be described with reference to FIG. 26. FIG. 26 is a schematic diagram illustrating the main part of a cross-sectional structure of the seventh modification of the present embodiment and corresponds to FIG. 18A.

For example, in the seventh modification, there is no insulating film 414 in the wiring layer 400T between the peripheral region (second region) L of the pad portion 402 and the semiconductor layer 400S facing the peripheral region L, between which space is entirely a hollow hole 422, namely, an air gap.

### 11.9 Eighth Modification

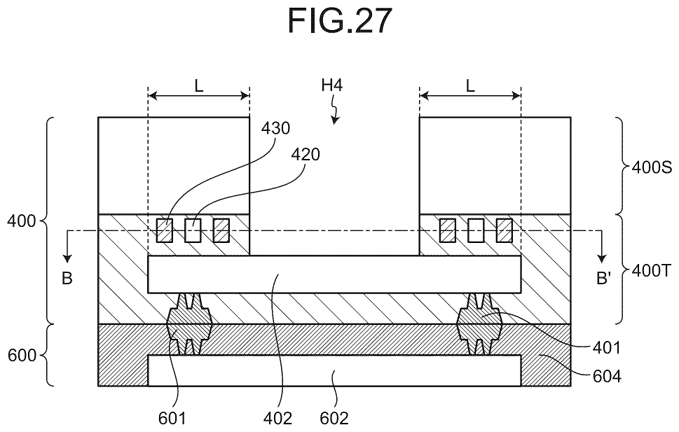

Furthermore, in the present embodiment, the air gap 420 may be interposed between metal dummies. Therefore, an eighth modification will be described with reference to FIG. 27. FIG. 27 is a schematic diagram illustrating the main part of a cross-sectional structure of the eighth modification of the present embodiment and corresponds to FIG. 18A.

For example, in the eighth modification, as illustrated in FIG. 27, an air gap 420 is interposed between metal dummies 430 that are rectangular similarly to the air gap 420. The metal dummy 430 is made of, for example, metal such as copper (Cu). In the present modification, by adopting the structure in which the air gap 420 is included between the metal dummies 430, the air gap 420 can be easily formed using an existing method of forming an air gap between pieces of wiring. Note that, in the present modification, the capacity value of the parasitic capacitance of the pad portion 402 increases by including the metal dummies 430 as compared with the present embodiment and the modifications described above; however, the capacitance of the parasitic capacitance can be reduced as compared with the case of the comparative example in which no air gaps 420 are provided at all.

Note that, in the present embodiment and the modifications, as described above, the inside of the air gap 420 is not limited to being filled with a gas such as air and may be filled with a low dielectric material having a dielectric constant & lower than that of the insulating film 414. In this case, the relative dielectric constant of the low dielectric material is at least smaller than 3.9 and, preferably, for example, around 2.6.

### 11.10 Manufacturing Method

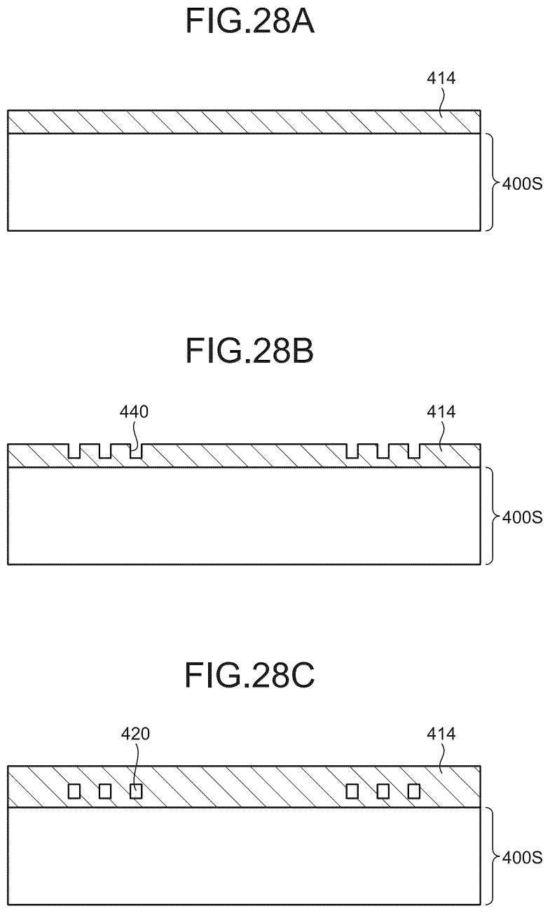

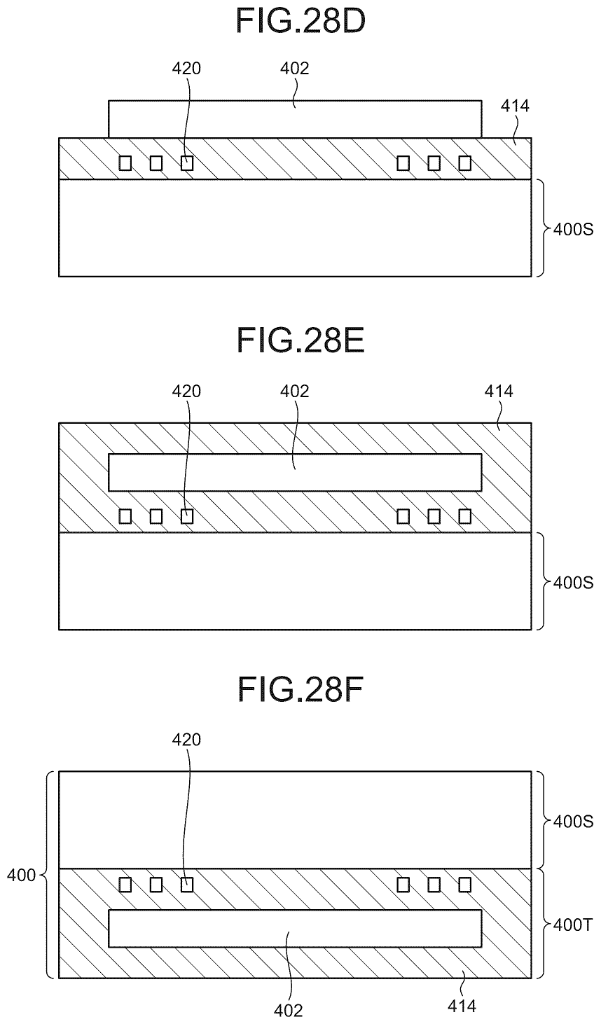

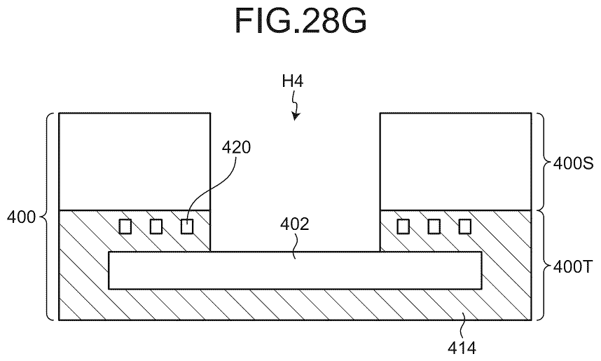

Next, a manufacturing method of the imaging device 1 according to the tenth embodiment will be described with reference to FIGS. 28A to 28G. FIGS. 28A to 28G are explanatory diagrams illustrating a part of the manufacturing method of the imaging device 1 according to the tenth embodiment of the present disclosure and are cross-sectional views corresponding to FIG. 18A.

As the manufacturing method in the present embodiment, two methods are mainly conceivable. The first one is a method of forming an air gap 420 when the wiring layer 400T is formed on the semiconductor layer 400S. In a case where this method is used, a plurality of air gaps 420 can be included at the same height in the wiring layer 400T.

For example, as illustrated in FIG. 28A, the insulating film 414 is stacked on the semiconductor layer 400S. Next, as illustrated in FIG. 28B, grooves 440 are formed on a surface of the insulating film 414. Furthermore, as illustrated in FIG. 28C, an insulating film 414 is stacked on the grooves 440 under such a condition that it is possible to avoid filling the grooves 440, whereby air gaps 420 are formed in the insulating film 414.

Furthermore, as illustrated in FIG. 28D, the pad portion 402 is formed on the insulating film 414. Next, as illustrated in FIG. 28E, an insulating film 414 is stacked in such a manner as to cover the pad portion 402. Then, as illustrated in FIG. 28F, the semiconductor layer 400S formed so far is turned upside down, and as illustrated in FIG. 28G, the opening H4 for exposing a part of the pad portion 402 is formed in the semiconductor layer 400S.

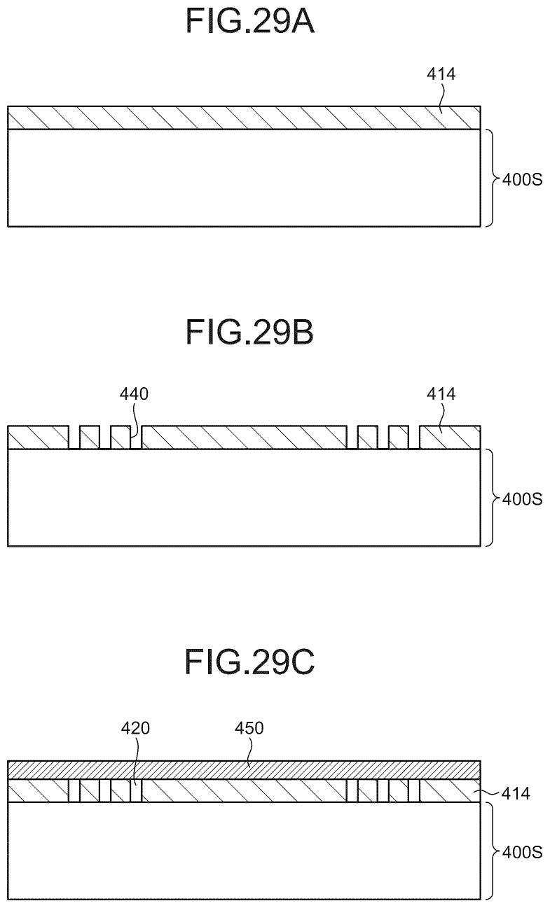

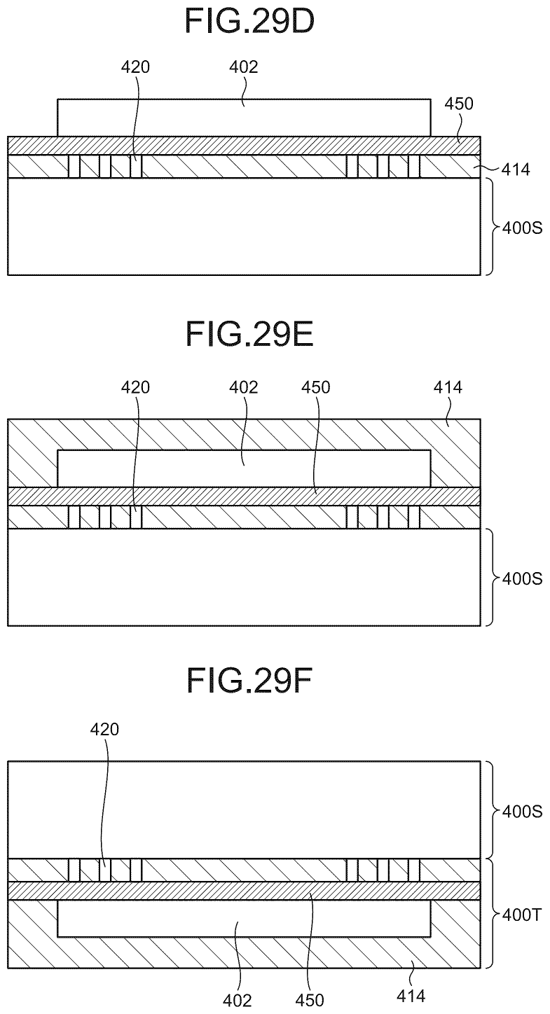

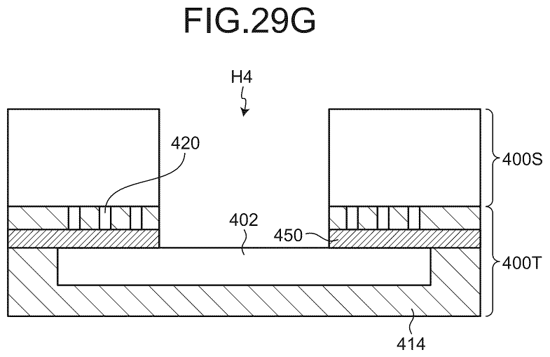

The other method is forming the air gaps 420 in a slit shape before the pad portion 402 is formed. Therefore, the other manufacturing method of the imaging device 1 according to the tenth embodiment will be described with reference to FIGS. 29A to 29G. FIGS. 29A to 29G are explanatory diagrams illustrating a part of the manufacturing method of the imaging device 1 according to the tenth embodiment of the present disclosure and are cross-sectional views corresponding to FIG. 18A.

For example, as illustrated in FIG. 29A, the insulating film 414 is stacked on the semiconductor layer 400S. Next, as illustrated in FIG. 29B, such slit-shaped grooves 440 that penetrate the insulating film 414 are formed. Furthermore, as illustrated in FIG. 29C, an insulating film 450 is formed in such a manner as to cover the grooves 440 while leaving the hollow holes, whereby the air gaps 420 are formed.

Furthermore, as illustrated in FIG. 29D, the pad portion 402 is formed on the insulating film 450. Next, as illustrated in FIG. 29E, an insulating film 414 is stacked in such a manner as to cover the pad portion 402. Then, as illustrated in FIG. 29F, the semiconductor layer 400S formed so far is turned upside down, and as illustrated in FIG. 29G, the opening H4 for exposing a part of the pad portion 402 is formed in the semiconductor layer 400S.

### 12. Summary

As described above, according to the embodiments of the present disclosure, by including the insulating film 404 in the semiconductor layer 400S facing the peripheral region (second region) L of pad portion 402 not exposed by the opening H4, the parasitic capacitance generated in the pad portion 402 can be reduced.

In addition, as described above, according to the embodiment, by including the air gaps 420 or a low dielectric between the peripheral region (second region) L of the pad portion 402 not exposed by the opening H4 and the semiconductor layer 400S facing the peripheral region L, the parasitic capacitance generated in the pad portion 402 can be reduced.

In the embodiments of the disclosure described above, the case where the present disclosure is applied to a back-illuminated CMOS image sensor structure has been described; however, embodiments of the present disclosure are not limited thereto and may be applied to a structure of other semiconductor devices.

Furthermore, the imaging device 1 according to the embodiment of the present disclosure can be manufactured by using a method, an apparatus, and conditions used for manufacturing a general semiconductor device. That is, the imaging device 1 according to the embodiment can be manufactured using existing manufacturing steps of semiconductor devices.

Note that examples of the above-described method include a physical vapor deposition (PVD) method, a chemical vapor deposition (CVD) method, and an atomic layer deposition (ALD) method. Examples of the PVD method include a vacuum vapor deposition method, an electron beam (EB) vapor deposition method, various sputtering methods (magnetron sputtering method, radio frequency (RF)-direct current (DC) coupled bias sputtering method, electron cyclotron resonance (ECR) sputtering method, counter target sputtering method, radio frequency sputtering method, and the like), an ion plating method, a laser ablation method, a molecular beam epitaxy (MBE) method, and a laser transfer method. Examples of the CVD method include a plasma CVD method, a thermal CVD method, an organic metal (MO) CVD method, and a photo-CVD method. Furthermore, examples of other methods include: an electroplating method, an electroless plating method, or a spin coating method; a dipping method; a cast method; a micro-contact printing; a drop cast method; various printing methods such as a screen printing method, an inkjet printing method, an offset printing method, a gravure printing method, and a flexographic printing method; a stamping method; a spray method; and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calender coater method. Furthermore, examples of the patterning method include chemical etching such as shadow masking, laser transfer, or photolithography and physical etching using ultraviolet rays, laser, or the like. In addition, examples of the planarization technology include a chemical mechanical polishing (CMP) method, a laser planarization method, a reflow method, and the like.

### 13. Application Examples

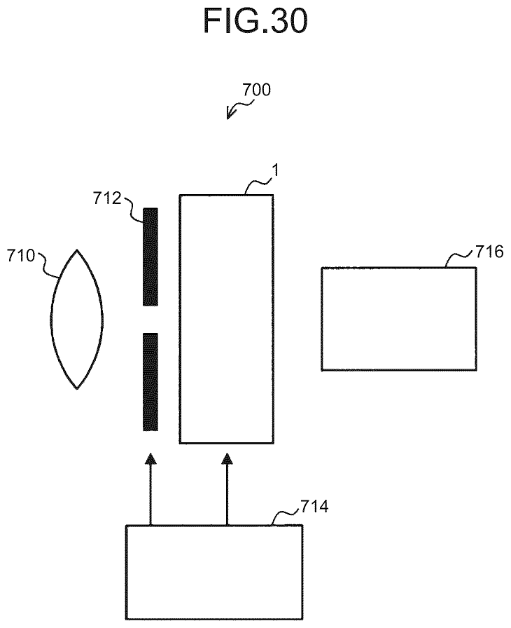

13.1 Application Example to Camera The technology according to the present disclosure (present technology) can be further applied to various products. For example, the technology according to the present disclosure may be applied to a camera or the like. Therefore, a configuration example of a camera 700 as an electronic device to which the present technology is applied will be described with reference to FIG. 30. FIG. 30 is an explanatory diagram illustrating an example of a schematic functional configuration of the camera 700 to which the technology according to the present disclosure (present technology) can be applied.

As illustrated in FIG. 30, the camera 700 includes an imaging device 1, an optical lens 710, a shutter mechanism 712, a drive circuit unit 714, and a signal processing circuit unit 716. The optical lens 710 forms an image of image light (incident light) from a subject on an imaging surface of the imaging device 1. As a result, signal charge is accumulated in pixels 541 of the imaging device 1 for a certain period of time. The shutter mechanism 712 opens and closes to control a light exposure period and a light shielding period for the imaging device 1. The drive circuit unit 714 supplies a drive signal for controlling a signal transfer operation of the imaging device 1, a shutter operation of the shutter mechanism 712, and the like to these units. That is, the imaging device 1 performs signal transfer on the basis of the drive signal (timing signal) supplied from the drive circuit unit 714. The signal processing circuit unit 716 performs various types of signal processing. For example, the signal processing circuit unit 716 outputs a video signal subjected to the signal processing to, for example, a storage medium (not illustrated) such as a memory or to a display unit (not illustrated).

The configuration example of the camera 700 has been described above. Each of the above components may be configured using a general-purpose member or may be configured by hardware specialized in the function of each component. Such a configuration can be modified as appropriate depending on the technical level at the time of implementation.

### 13.2 Application Example to Smartphone

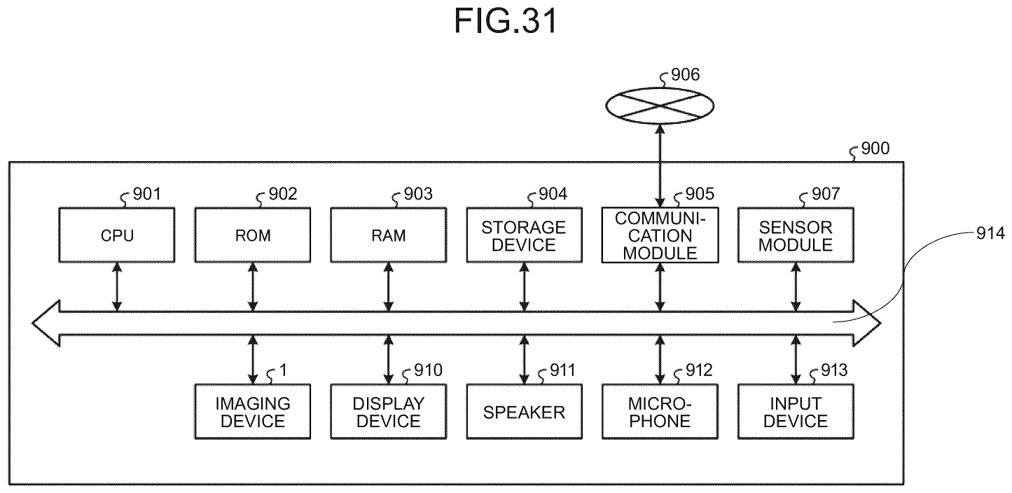

For example, the technology according to the present disclosure may be applied to a smartphone or the like. Therefore, a configuration example of a smartphone 900 as an electronic device to which the present technology is applied will be described with reference to FIG. 31. FIG. 31 is a block diagram illustrating an example of a schematic functional configuration of the smartphone 900 to which the technology according to the present disclosure (present technology) can be applied.

As illustrated in FIG. 31, the smartphone 900 includes a central processing unit (CPU) 901, a read only memory (ROM) 902, and a random access memory (RAM) 903. The smartphone 900 further includes a storage device 904, a communication module 905, and a sensor module 907. Furthermore, the smartphone 900 includes an imaging device 1, a display device 910, a speaker 911, a microphone 912, an input device 913, and a bus 914. Furthermore, the smartphone 900 may include a processing circuit such as a digital signal processor (DSP) instead of or in addition to the CPU 901.

The CPU 901 functions as an arithmetic processing device and a control device and controls the overall operation in the smartphone 900 or a part thereof in accordance with various programs recorded in the ROM 902, the RAM 903, the storage device 904, or the like. The ROM 902 stores programs, operation parameters, and the like used by the CPU 901. The RAM 903 primarily stores programs used in execution by the CPU 901, parameters that vary as appropriate in the execution, and the like. The CPU 901, the ROM 902, and the RAM 903 are connected to each other by the bus 914. In addition, the storage device 904 is a device for data storage configured as an example of a storage unit of the smartphone 900. The storage device 904 includes, for example, a magnetic storage device such as a hard disk drive (HDD), a semiconductor storage device, an optical storage device, and the like. The storage device 904 stores programs and various types of data executed by the CPU 901, various types of data acquired from the outside, and the like.

The communication module 905 is a communication interface including, for example, a communication device for connecting to a communication network 906. The communication module 905 can be, for example, a communication card for wired or wireless local area network (LAN), Bluetooth (registered trademark), wireless USB (WUSB) or the like. Furthermore, the communication module 905 may be a router for optical communication, a router for asymmetric digital subscriber line (ADSL), a modem for various types of communication, or the like. The communication module 905 transmits and receives signals and the like to and from the Internet or other communication devices using a predetermined protocol such as Transmission Control Protocol (TCP)/Internet Protocol (IP). Furthermore, the communication network 906 connected to the communication module 905 is a network connected in a wired or wireless manner and is, for example, the Internet, a home LAN, infrared communication, satellite communication, or the like. The sensor module 907 includes various sensors

such as a motion sensor (for example, an acceleration sensor, a gyro sensor, a geomagnetic sensor, or the like), a biological information sensor (for example, a pulse sensor, a blood pressure sensor, a fingerprint sensor, and the like), or a position sensor (for example, a global navigation satellite system (GNSS) receiver or the like).

The imaging device 1 is provided on a surface of the smartphone 900 and can capture an image of an object or the like located on the back side or the front side of the smartphone 900. Specifically, the technology according to the present disclosure (the present technology) can be applied to the imaging device 1. Furthermore, the imaging device 1 can further include an optical system mechanism (not illustrated) including an imaging lens, a zoom lens, a focus lens, and the like and a drive system mechanism (not illustrated) that controls the operation of the optical system mechanism. Furthermore, the imaging elements can collect incident light from an object as an optical image, and the signal processing circuit can photoelectrically convert a formed optical image for every pixel, read a signal of each pixel as an imaging signal, and perform image processing to acquire a captured image.

The display device 910 is provided on a surface of the smartphone 900 and can be a display device such as a liquid crystal display (LCD) or an organic electro luminescence (EL) display. The display device 910 can display an operation screen, a captured image acquired by the above-described imaging device 1, and others.

The speaker 911 can output, for example, a call voice, a voice accompanying the video content displayed by the display device 910 described above, and the like to a user.

The microphone 912 can collect, for example, a call voice of the user, a voice including a command to activate a function of the smartphone 900, and a voice in a surrounding environment of the smartphone 900.

The input device 913 is a device operated by the user, such as a button, a keyboard, a touch panel, or a mouse. The input device 913 includes an input control circuit that generates an input signal on the basis of information input by the user and outputs the input signal to the CPU 901. By operating the input device 913, the user can input various types of data to the smartphone 900 or give an instruction on a processing operation.

The configuration example of the smartphone 900 has been described above. Each of the above components may be configured using a general-purpose member or may be configured by hardware specialized in the function of each component. Such a configuration can be modified as appropriate depending on the technical level at the time of implementation.

### 14. Supplements

Although the preferred embodiments of the disclosure have been described in detail by referring to the accompanying drawings, the technical scope of the disclosure is not limited to such examples. It is obvious that a person having ordinary knowledge in the technical field of the present disclosure can conceive various modifications or variations within the scope of the technical idea described in the claims, and it is naturally understood that these also belong to the technical scope of the present disclosure.

Incidentally, the effects described in the present specification are merely illustrative or exemplary and are not limiting. That is, the technology according to the present disclosure can achieve other effects that are obvious to those skilled in the art from the description of the present specification together with or in place of the above effects.

Note that the present technology can also have the following configurations.
(1) A semiconductor device comprising:
   a first substrate including a wiring layer having an electrode and a semiconductor layer stacked on the wiring layer;
   an opening included in such a manner as to penetrate the semiconductor layer in such a manner as to expose a first region of the electrode; and
   an insulating film included in the semiconductor layer facing a second region of the electrode not exposed by the opening.
(2) The semiconductor device according to (1), wherein the insulating film is included in such a manner as to occupy ½ or more of the semiconductor layer facing the second region of the electrode.
(3) The semiconductor device according to (2), wherein the insulating film is included over the entire semiconductor layer facing the second region of the electrode.
(4) The semiconductor device according to (2), wherein the insulating film is included in a part of the semiconductor layer facing the second region of the electrode.
(5) The semiconductor device according to (4), wherein a plurality of the insulating films is included in the semiconductor layer facing the second region of the electrode.
(6) The semiconductor device according to (5), wherein the plurality of the insulating films is alternately included with the semiconductor layer interposed therebetween in a cross section of the semiconductor device taken along a stacking direction of the wiring layer and the semiconductor layer.
(7) The semiconductor device according to (6), wherein each of the insulating films has a rectangular shape in the cross section.
(8) The semiconductor device according to (7), wherein, in the cross section, a relationship between a length d of each of the insulating films along the stacking direction and a width W of each of the insulating films along a direction orthogonal to the stacking direction satisfies W/2<d.
(9) The semiconductor device according to (6), wherein, in the cross section, each of the insulating films has a trapezoidal shape or a shape obtained by joining two trapezoids with either upper bases or lower bases of the trapezoids joined together.
(10) The semiconductor device according to (5), wherein the plurality of the insulating films is included in such a manner as to surround the opening when viewed from above the semiconductor layer.
(11) The semiconductor device according to (5), wherein the plurality of the insulating films is included in such a manner as to extend along any side of the opening having a rectangular shape when viewed from above the semiconductor layer.
(12) The semiconductor device according to (4), wherein the insulating film is included in a lattice shape around the opening when viewed from above the semiconductor layer.
(13) The semiconductor device according to (4), wherein the insulating film is included in a spiral shape around the opening when viewed from above the semiconductor layer.
(14) The semiconductor device according to (5), wherein the plurality of the insulating films is included in dots shape around the opening when viewed from above the semiconductor layer.
(15) The semiconductor device according to any one of (1) to (14), wherein the insulating film is made of at least one selected from a group consisting of a silicon oxide, a silicon nitride, a silicon oxynitride, a silicon carbide, a silicon carbonitride, an organic insulating material, a metal oxide, a metal oxynitride, and a low dielectric constant material.
(16) The semiconductor device according to any one of (1) to (15), wherein the insulating film includes an air gap.
(17) A semiconductor device comprising:
   a first substrate including a wiring layer having an electrode and a semiconductor layer stacked on the wiring layer;
   an opening included in such a manner as to penetrate the semiconductor layer in such a manner as to expose a first region of the electrode; and
   an air gap included between a second region of the electrode not exposed by the opening and the semiconductor layer facing the second region.
(18) The semiconductor device according to any one of (1) to (17), wherein the semiconductor layer includes an imaging element.
(19) The semiconductor device according to any one of (1) to (18), wherein the electrode is electrically connected to an element located outside the semiconductor device.
(20) The semiconductor device according to any one of (1) to (19), further comprising a second substrate on which the first substrate is stacked, wherein the first substrate and the second substrate are bonded by bonding electrodes each included in one of the first substrate and the second substrate.
(21) An electronic device on which a semiconductor device is mounted,
   wherein the semiconductor device comprises:
   a first substrate including a wiring layer having an electrode and a semiconductor layer stacked on the wiring layer;
   an opening included in such a manner as to penetrate the semiconductor layer in such a manner as to expose a first region of the electrode; and
   an insulating film included in the semiconductor layer facing a second region of the electrode not exposed by the opening.

### REFERENCE SIGNS LIST

1 IMAGING DEVICE
100, 200, 300, 400, 600 SEMICONDUCTOR SUBSTRATE
100S, 200S, 300S, 400S SEMICONDUCTOR LAYER
100T, 200T, 300T, 400T, 602 WIRING LAYER
201, 202, 301, 302, 401, 601 CONTACT SECTION
201R, 202R, 301R, 302R CONTACT REGION
402, 612 PAD PORTION
404, 414, 450, 604 INSULATING FILM
406 MASK
408, H3, H4 OPENING
410, 440 GROOVE
416, 422 HOLLOW HOLE
420 AIR GAP
430 METAL DUMMY
510A INPUT SECTION
510B OUTPUT SECTION
511 INPUT TERMINAL
512 INPUT CIRCUIT SECTION
513 INPUT AMPLITUDE MODIFYING SECTION
514 INPUT DATA CONVERTING CIRCUIT SECTION
515 OUTPUT DATA CONVERTING CIRCUIT SECTION
516 OUTPUT AMPLITUDE MODIFYING SECTION
517 OUTPUT CIRCUIT SECTION
518 OUTPUT TERMINAL
520 ROW DRIVE SECTION
530 TIMING CONTROL SECTION
540 PIXEL ARRAY SECTION
541 PIXEL
542 ROW DRIVE SIGNAL LINE
543 VERTICAL SIGNAL LINE
544 POWER SUPPLY LINE
550 COLUMN SIGNAL PROCESSING SECTION
560 IMAGE SIGNAL PROCESSING SECTION
700 CAMERA
710 OPTICAL LENS
712 SHUTTER MECHANISM
714 DRIVE CIRCUIT UNIT
716 SIGNAL PROCESSING CIRCUIT UNIT
900 SMARTPHONE
901 CPU
902 ROM
903 RAM
904 STORAGE DEVICE
905 COMMUNICATION MODULE
906 COMMUNICATION NETWORK
907 SENSOR MODULE
910 DISPLAY DEVICE
911 SPEAKER
912 MICROPHONE
913 INPUT DEVICE
914 BUS
H1, H2 CONNECTION HOLE
L PERIPHERAL REGION

1. A semiconductor device comprising:
a first substrate including a wiring layer having an electrode and a semiconductor layer stacked on the wiring layer;
an opening included in such a manner as to penetrate the semiconductor layer in such a manner as to expose a first region of the electrode; and
an insulating film included in the semiconductor layer facing a second region of the electrode not exposed by the opening.

2. The semiconductor device according to claim 1, wherein the insulating film is included in such a manner as to occupy ½ or more of the semiconductor layer facing the second region of the electrode.

3. The semiconductor device according to claim 2, wherein the insulating film is included over the entire semiconductor layer facing the second region of the electrode.

4. The semiconductor device according to claim 2, wherein the insulating film is included in a part of the semiconductor layer facing the second region of the electrode.

5. The semiconductor device according to claim 4, wherein a plurality of the insulating films is included in the semiconductor layer facing the second region of the electrode.

6. The semiconductor device according to claim 5, wherein the plurality of the insulating films is alternately included with the semiconductor layer interposed therebetween in a cross section of the semiconductor device taken along a stacking direction of the wiring layer and the semiconductor layer.

7. The semiconductor device according to claim 6, wherein each of the insulating films has a rectangular shape in the cross section.

8. The semiconductor device according to claim 7, wherein, in the cross section, a relationship between a length d of each of the insulating films along the stacking direction and a width W of each of the insulating films along a direction orthogonal to the stacking direction satisfies W/2<d.

9. The semiconductor device according to claim 6, wherein, in the cross section, each of the insulating films has a trapezoidal shape or a shape obtained by joining two trapezoids with either upper bases or lower bases of the trapezoids joined together.

10. The semiconductor device according to claim 5, wherein the plurality of the insulating films is included in such a manner as to surround the opening when viewed from above the semiconductor layer.

11. The semiconductor device according to claim 5, wherein the plurality of the insulating films is included in such a manner as to extend along any side of the opening having a rectangular shape when viewed from above the semiconductor layer.

12. The semiconductor device according to claim 4, wherein the insulating film is included in a lattice shape around the opening when viewed from above the semiconductor layer.

13. The semiconductor device according to claim 4, wherein the insulating film is included in a spiral shape around the opening when viewed from above the semiconductor layer.

14. The semiconductor device according to claim 5, wherein the plurality of the insulating films is included in dots shape around the opening when viewed from above the semiconductor layer.

15. The semiconductor device according to claim 1, wherein the insulating film is made of at least one selected from a group consisting of a silicon oxide, a silicon nitride, a silicon oxynitride, a silicon carbide, a silicon carbonitride, an organic insulating material, a metal oxide, a metal oxynitride, and a low dielectric constant material.

16. The semiconductor device according to claim 1, wherein the insulating film includes an air gap.

17. The semiconductor device according to claim 1, wherein the semiconductor layer includes an imaging element.

18. The semiconductor device according to claim 1, wherein the electrode is electrically connected to an element located outside the semiconductor device.

19. The semiconductor device according to claim 1, further comprising a second substrate on which the first substrate is stacked, wherein the first substrate and the second substrate are bonded by bonding electrodes each included in one of the first substrate and the second substrate.

20. An electronic device on which a semiconductor device is mounted,
wherein the semiconductor device comprises:
a first substrate including a wiring layer having an electrode and a semiconductor layer stacked on the wiring layer;
an opening included in such a manner as to penetrate the semiconductor layer in such a manner as to expose a first region of the electrode; and
an insulating film included in the semiconductor layer facing a second region of the electrode not exposed by the opening.
